(19) United States
(12) Patent Application Publication
(10) Pub. No.: US 2023/0107142 A1
(43) Pub. Date: Apr. 6, 2023

(54) SUBSTRATE TREATING METHOD AND APPARATUS USED THEREFOR

(71) Applicant: SCREEN HOLDINGS CO., LTD., Kyoto (JP)

(72) Inventors: Yuta SASAKI, Kyoto (JP); Yosuke HANAWA, Kyoto (JP); Shogo KUNIEDA, Kyoto (JP)

(21) Appl. No.: 17/893,750

(22) Filed: Aug. 23, 2022

(30) Foreign Application Priority Data
Sep. 22, 2021 (JP) 2021-154385

(51) Int. Cl. B05D 3/04; H01L 21/67; B05D 1/00

(52) U.S. Cl. CPC B05D 3/046; B05D 1/002; H01L 21/67034

(57) ABSTRACT

Provided is a substrate treating method for drying a substrate on which a pattern is formed. The method includes: a solidified film forming liquid supplying step, an entire surface coating step, a solidified film forming step, and a sublimation step. The entire surface coating step causes the substrate to rotate at a number of rotations for solidified film formation in accordance with a relationship among a concentration of a sublimable substance, a target solidified film thickness as a desired film thickness of a solidified film, and the number of rotations for solidified film formation as a number of rotations of the substrate for forming the solidified film of the target solidified film thickness when the concentration of the sublimable substance is a predetermined concentration.

### BACKGROUND OF THE INVENTION

### Field of the Invention

The present invention relates to a substrate treating method and an apparatus used therefor for forming patterns on substrates, such as semiconductor substrates, substrates for flat panel display (FPD) like liquid crystal display and organic electroluminescence (EL) display, glass substrates for photomask, optical disk substrates, and for drying the substrates where the patterns are formed.

### 2. Description of the Related Art

Examples of such a currently-used substrate treating method of this type include sublimation drying with use of a solidified film forming liquid containing a sublimable substance. See, for example, Japanese Unexamined Patent Application Publication No. 2020-4948A as Patent Literature 1.

In the Patent Literature 1, a substrate where a pattern is formed is treated with a chemical liquid, and then the chemical liquid is replaced by a replacement solution having high affinity for a sublimable substance. Then, a solidified film forming liquid is supplied to a top face of the substrate where the pattern is formed. The solidified film forming liquid contains a sublimable substance and a solvent, and the sublimable substance has an adjusted constant concentration. After the pattern on the substrate is covered with the solidified film forming liquid, the solvent is evaporated from the solidified film forming liquid supplied to the substrate. This can form a solidified film constituted by the sublimable substance over the top face of the substrate. Thereafter, the solidified film is sublimated and thereby removed from a surface of the substrate. This allows the top face of the substrate W to be dried entirely while reducing collapse of the pattern due to the liquid like the chemical liquid and the replacement solution.

It has been known in the sublimation drying described above that a collapse rate of the pattern depends on a relationship between a height of the pattern formed on the substrate and a height of the solidified film formed on the entire of the top face of the substrate. That is, as shown in FIG. 11 of the Patent Literature 1, a collapse rate is low in a predetermined range where an embedding ratio indicating a ratio of the height of the solidified film to the height of the pattern falls around 100%. On the other hand, a collapse rate increases as an embedding ratio falls out of the predetermined range. In other words, if the embedding ratio falls out of the predetermined range including 100%, a treatment error occurs.

Then, a substrate treating method has been proposed to prevent such a treatment error. See, for example, Japanese Unexamined Patent Application Publication No. 2020-107842A as Patent Literature 2.

However, the example of the currently-used apparatus with such a configuration has the following problems.

Specifically, in the currently-used apparatus, if treatment is determined to be inappropriate, the treatment has to stop in midstream and the concentration of the solidified film forming liquid has to be controlled for re-forming the solidified film. This may largely reduce throughput. Moreover, an excessive solvent or an excessive sublimable substance has to be supplied for concentration control of the solidified film forming liquid. This may increase manufacturing costs.

### SUMMARY OF THE INVENTION

The present invention has been made regarding the state of the art noted above, and its object is to provide a substrate treating method and an apparatus used therefor that can treat a substrate by rotating the substrate to perform suitable treatment in accordance with a predetermined relationship without reducing throughput or increasing manufacturing costs.

The present invention is constituted as stated below to achieve the above object.

One aspect of the present invention provides a substrate treating method for drying a substrate on which a pattern is formed. The method includes: a solidified film forming liquid supplying step of supplying a solidified film forming liquid, containing a sublimable substance and a solvent, to the substrate; an entire surface coating step of forming a liquid film of the solidified film forming liquid by rotating the substrate and spreading the solidified film forming liquid over an entire top face of the substrate; a solidified film forming step of forming a solidified film containing the sublimable substance over the top face of the substrate by evaporating the solvent from the liquid film of the solidified film forming liquid and depositing the sublimable substance from the liquid film of the solidified film forming liquid; and a sublimating step of sublimating the solidified film to remove the solidified film from the substrate. The entire surface coating step causes the substrate to rotate at a number of rotations for solidified film formation in accordance with a relationship among a concentration of the sublimable substance in the solidified film forming liquid, a target solidified film thickness as a desired film thickness of the solidified film formed on the entire top face of the substrate by depositing the sublimable substance from the liquid film of the solidified film forming liquid, and the number of rotations for solidified film formation as a number of rotations of the substrate for forming the solidified film of the target solidified film thickness when the concentration of the sublimable substance in the solidified film forming liquid is a predetermined concentration.

According to the aspect of the present invention, the solidified film forming liquid is supplied to the substrate in the solidified film forming liquid supplying step. The solidified film forming liquid is spread over the entire top face of the substrate in the entire surface coating step. The solvent evaporates from the liquid film of the solidified film forming liquid to form the solidified film on the entire top face of the substrate in the solidified film forming step. The solidified film is sublimated to remove the solidified film from the substrate in the sublimating step. The substrate is treated in this series of steps. In the entire surface coating step, the substrate is rotated at the number of rotations for solidified film formation in accordance with a relationship among the concentration, the target solidified film thickness, and the number of rotations for solidified film formation. Consequently, a solidified film having an intended target solidified film thickness can be formed in accordance with the concentration of the sublimable substance by rotating the substrate at a number of rotations of the substrate adopted for the relationship between the concentration and the target solidified film thickness. As a result, there is no need to readjust the concentration of the solidified film forming liquid, and thus a substrate can be treated without reducing throughput or increasing manufacturing costs.

Another aspect of the present invention provides a substrate treating method for drying a substrate on which a pattern is formed. The method includes: a solidified film forming liquid supplying step of supplying a solidified film forming liquid, containing a sublimable substance and a solvent, to the substrate; an entire surface coating step of forming a liquid film of the solidified film forming liquid by rotating the substrate and spreading the solidified film forming liquid over an entire top face of the substrate; a solidified film forming step of forming a solidified film containing the sublimable substance over the top face of the substrate by evaporating the solvent from the liquid film of the solidified film forming liquid and depositing the sublimable substance from the liquid film of the solidified film forming liquid; and a sublimating step of sublimating the solidified film to remove the solidified film from the substrate. The entire surface coating step causes the substrate to rotate at a number of rotations for liquid film formation in accordance with a relationship among a concentration of the sublimable substance in the solidified film forming liquid, a target liquid film thickness as a desired film thickness of the liquid film of the solidified film forming liquid, and the number of rotations for liquid film formation as a number of rotations of the substrate for forming the liquid film of the target liquid film thickness when the concentration of the sublimable substance in the solidified film forming liquid is a predetermined concentration.

According to the aspect of the present invention, the solidified film forming liquid is supplied to the substrate in the solidified film forming liquid supplying step. The solidified film forming liquid is spread over the entire top face of the substrate in the entire surface coating step. The solvent evaporates from the liquid film of the solidified film forming liquid to form the solidified film on the entire top face of the substrate in the solidified film forming step. The solidified film is sublimated to remove the solidified film from the substrate in the sublimating step. The substrate is treated in this series of steps. In the entire surface coating step, the substrate is rotated at the number of rotations for liquid film formation in accordance with a relationship among the concentration, the target liquid film thickness, and the number of rotations for liquid film formation. Consequently, a liquid film having an intended target liquid film thickness can be formed in accordance with the concentration of the sublimable substance by rotating the substrate at the number of rotations of the substrate adopted for the relationship between the concentration and the target liquid film thickness. As a result, there is no need to readjust the concentration of the solidified film forming liquid, and thus a substrate can be treated without reducing throughput or increasing manufacturing costs.

Moreover, it is preferred in the aspect of the present invention that the relationship is a correlation among the concentration, the target solidified film thickness, and the number of rotations for solidified film formation, the correlation is expressed by an approximate equation representing a change in the target solidified film thickness with respect to a change in either the concentration or the number of rotations for solidified film formation, and the number of rotations for solidified film formation is determined in accordance with the approximate equation.

The relationship is a correlation among the concentration, the target solidified film thickness, and the number of rotations for solidified film formation. This correlation is expressed by an approximate equation representing a change in the target solidified film thickness with respect to a change in either the concentration or the number of rotations for solidified film formation. Using the approximate equation can determine a number of rotations for solidified film formation at which treatment is suitably performed.

Moreover, it is preferred in the aspect of the present invention that the relationship is a correlation among the concentration, the target liquid film thickness, and the number of rotations for liquid film formation, the correlation is expressed by an approximate equation representing a change in the target liquid film thickness with respect to a change in either the concentration or the number of rotations for liquid film formation, and the number of rotations for liquid film formation is determined in accordance with the approximate equation.

The relationship is a correlation among the concentration, the target liquid film thickness, and the number of rotations for liquid film formation. This correlation is expressed by an approximate equation representing a change in the target liquid film thickness with respect to a change in either the concentration or the number of rotations for liquid film formation. Using the approximate equation can determine a number of rotations for liquid film formation at which treatment is suitably performed.

It is preferred in the aspect of the present invention that, when a variation of the concentration of the sublimable substance in the solidified film forming liquid occurs from the predetermined concentration, the number of rotations for solidified film formation is determined based on the relationship in accordance with the variation of the concentration.

The number of rotations for solidified film formation at which treatment is suitably performed can be determined based on the relationship among the concentration, the target solidified film thickness, and the number of rotations for solidified film formation.

It is preferred in the aspect of the present invention that, when a variation of the concentration of the sublimable substance in the solidified film forming liquid occurs from the predetermined concentration, the number of rotations for liquid film formation is determined based on the relationship in accordance with the variation of the concentration.

The number of rotations for liquid film formation at which treatment is suitably performed can be determined based on the concentration, the target liquid film thickness, and the number of rotations for liquid film formation.

Moreover, it is preferred in the entire surface coating step according to the aspect of the present invention that, before the substrate is rotated at the number of rotations for solidified film formation, the substrate is rotated at a number of rotations smaller than the number of rotations for solidified film formation for spreading the solidified film forming liquid over the entire top face of the substrate.

The solidified film forming liquid can be supplied at a number of rotations smaller than the number of rotations for solidified film formation. This can suppress scattering of the solidified film forming liquid, leading to suppressed consumption of the solidified film forming liquid.

Moreover, it is preferred in the entire surface coating step according to the aspect of the present invention that, before the substrate is rotated at the number of rotations for liquid film formation, the substrate is rotated at a number of rotations smaller than the number of rotations for liquid film formation for spreading the solidified film forming liquid over the entire top face of the substrate.

The solidified film forming liquid can be supplied at a number of rotations smaller than the number of rotations for liquid film formation. This can suppress scattering of the solidified film forming liquid, leading to suppressed consumption of the solidified film forming liquid.

Moreover, it is preferred in the aspect of the present invention that the concentration of the solidified film forming liquid is measured before the solidified film forming liquid supplying step.

This can detect a variation in the concentration before supplying the solidified film forming liquid to the substrate. As a result, the number of rotations for solidified film formation can be changed without hurrying.

Moreover, it is preferred in the aspect of the present invention that the concentration of the solidified film forming liquid is measured at the top face of the substrate in the solidified film forming liquid supplying step.

This can detect a variation in the concentration even if a supply system of the solidified film forming liquid has some abnormality. Consequently, inappropriate treatment caused by the variation in the concentration can surely be prevented.

Another aspect of the present invention provides a substrate treating apparatus for drying a substrate. The substrate treating apparatus includes a spin holder configured to hold a substrate with a pattern formed thereon in a horizontal attitude and to rotate the substrate in a horizontal plane, and a solidified film forming liquid supplying unit configured to supply a solidified film forming liquid, containing a sublimable substance and a solvent, to a top face of the substrate held by the spin holder. The spin holder spins to rotate the substrate, thereby spreading the solidified film forming liquid, supplied from the solidified film forming liquid supplying unit to the top face of the substrate, over the entire top face of the substrate to form a liquid film of the solidified film forming liquid. The solvent evaporates from the liquid film of the solidified film forming liquid and the sublimable substance is deposited from the liquid film of the solidified film forming liquid to form a solidified film, containing the sublimable substance, over the entire top face of the substrate. The solidified film is sublimated and removed from the substrate. The substrate treating apparatus further includes: a memory unit configured to store in advance a relationship among a concentration of the sublimable substance in the solidified film forming liquid, a target solidified film thickness as a desired film thickness of the solidified film formed on the entire top face of the substrate by depositing the sublimable substance from the liquid film of the solidified film forming liquid, and a number of rotations for solidified film formation as a number of rotations of the substrate for forming the solidified film of the target solidified film thickness when the concentration of the sublimable substance in the solidified film forming liquid is a predetermined concentration; and a controller configured to control the spin holder in accordance with the relationship stored in the memory unit such that the substrate rotates at the number of rotations for solidified film formation.

According to the aspect of the present invention, the controller treats the substrate by rotating the substrate by the spin holder, spreading the solidified film forming liquid over the entire top face of the substrate, evaporating the solvent from the liquid film of the solidified film forming liquid to form a solidified film containing the sublimable substance over the entire top face of the substrate, sublimating the solidified film, and removing the solidified film from the substrate. At this time, the controller controls the spin holder based on the relationship stored in the memory unit such that the substrate rotates at a number of rotations for solidified film formation. Consequently, a liquid film having an intended target liquid film thickness can be formed in accordance with the concentration of the sublimable substance by rotating the substrate at the number of rotations of the substrate adopted for the relationship between the concentration and the target liquid film thickness. As a result, there is no need to readjust the concentration of the solidified film forming liquid, and thus a substrate can be treated without reducing throughput or increasing manufacturing costs.

Another aspect of the present invention provides a substrate treating apparatus for drying a substrate. The substrate treating apparatus includes a spin holder configured to hold a substrate with a pattern formed thereon in a horizontal attitude and to rotate the substrate in a horizontal plane, and a solidified film forming liquid supplying unit configured to supply a solidified film forming liquid, containing a sublimable substance and a solvent, to a top face of the substrate held by the spin holder. The spin holder spins to rotate the substrate, thereby spreading the solidified film forming liquid, supplied from the solidified film forming liquid supplying unit to the top face of the substrate, over the entire top face of the substrate to form a liquid film of the solidified film forming liquid. The solvent evaporates from the liquid film of the solidified film forming liquid and the sublimable substance is deposited from the liquid film of the solidified film forming liquid to form a solidified film, containing the sublimable substance, over the entire top face of the substrate. The solidified film is sublimated and removed from the substrate. The substrate treating apparatus further includes: a memory unit configured to store in advance a relationship among a concentration of the sublimable substance in the solidified film forming liquid, a target liquid film thickness as a desired film thickness of the solidified film forming liquid formed on the top face of the substrate, and a number of rotations for liquid film formation as a number of rotations of the substrate for forming the liquid film of the target liquid film thickness when the concentration of the sublimable substance in the solidified film forming liquid is a predetermined concentration; and a controller configured to control the spin holder in accordance with the relationship stored in the memory unit such that the substrate rotates at the number of rotations for liquid film formation.

According to the aspect of the present invention, the controller treats the substrate by rotating the substrate by the spin holder, spreading the solidified film forming liquid over the entire top face of the substrate, evaporating the solvent from the liquid film of the solidified film forming liquid to form a solidified film containing the sublimable substance over the entire top face of the substrate, sublimating the solidified film, and removing the solidified film from the substrate. At this time, the controller controls the spin holder based on the relationship stored in the memory unit such that the substrate rotates at a number of rotations for liquid film formation. Consequently, a liquid film having an intended target liquid film thickness can be formed in accordance with the concentration of the sublimable substance by rotating the substrate at the number of rotations of the substrate adopted for the relationship between the concentration and the target liquid film thickness. As a result, there is no need to readjust the concentration of the solidified film forming liquid, and thus a substrate can be treated without reducing throughput or increasing manufacturing costs.

Moreover, it is preferred in the aspect of the present invention that the relationship stored in the memory unit is a correlation among the concentration, the target solidified film thickness, and the number of rotations for solidified film formation, the correlation is a correlation expressed by an approximate equation representing a change in the target solidified film thickness with respect to a change in either the concentration or the number of rotations for solidified film formation, and the controller reads the correlation among the concentration, the target solidified film thickness, and the number of rotations for solidified film formation from the memory unit, and determines the number of rotations for solidified film formation based on the correlation.

The relationship is a correlation among the concentration, the target solidified film thickness, and the number of rotations for solidified film formation. This correlation is expressed by an approximate equation representing a change in the target solidified film thickness with respect to a change in either the concentration or the number of rotations for solidified film formation. Using the correlation can determine a number of rotations for solidified film formation at which treatment is suitably performed.

Moreover, it is preferred in the aspect of the present invention that the relationship stored in the memory unit is a correlation among the concentration, the target liquid film thickness, and the number of rotations for liquid film formation, the correlation is a correlation expressed by an approximate equation representing a change in the target liquid film thickness with respect to a change in either the concentration or the number of rotations for liquid film formation, and the controller reads the correlation among the concentration, the target liquid film thickness, and the number of rotations for liquid film formation from the memory unit, and determines the number of rotations for liquid film formation based on the correlation.

The relationship is a correlation among the concentration, the target liquid film thickness, and the number of rotations for liquid film formation. This correlation is expressed by an approximate equation representing a change in the target liquid film thickness with respect to a change in either the concentration or the number of rotations for liquid film formation. The controller can determine a number of rotations for liquid film formation at which treatment is suitably performed with use of the correlation.

Moreover, it is preferred in the aspect of the present invention that, before the controller controls the spin holder such that the substrate is rotated at the number of rotations for solidified film formation, the controller controls the spin holder so as to rotate the substrate at a number of rotations smaller than the number of rotations for solidified film formation for spreading the solidified film forming liquid over the entire top face of the substrate.

The controller controls the spin holder at the number of rotations smaller than the number of rotations for solidified film formation. Consequently, the solidified film forming liquid can be supplied at a small number of rotations. This can suppress scattering of the solidified film forming liquid, leading to suppressed consumption of the solidified film forming liquid.

Moreover, it is preferred in the aspect of the present invention that, before the controller controls the spin holder such that the substrate is rotated at the number of rotations for liquid film formation, the controller controls the spin holder so as to rotate the substrate at a number of rotations smaller than the number of rotations for liquid film formation for spreading the solidified film forming liquid over the entire top face of the substrate.

The controller controls the spin holder at the number of rotations smaller than the number of rotations for liquid film formation. Consequently, the solidified film forming liquid can be supplied at a small number of rotations. This can suppress scattering of the solidified film forming liquid, leading to suppressed consumption of the solidified film forming liquid.

It is preferred in the aspect of the present invention that the substrate treating apparatus further includes a concentration detector configured to detect a concentration of the sublimable substance in the solidified film forming liquid, and that when a detection result of the concentration detector reveals that a variation of the concentration of the sublimable substance in the solidified film forming liquid occurs from the predetermined concentration, the controller determines the number of rotations for solidified film formation based on the relationship stored in the memory unit in accordance with the variation of the concentration.

The controller determines the number of rotations for solidified film formation based on the relationship stored in the memory unit in accordance with the variation in the concentration when the detection result of the concentration detector reveals that the concentration of the sublimable substance in the solidified film forming liquid varies from the predetermined concentration. Consequently, even when treatment is determined inappropriate due to the variation in the concentration in the solidified film forming liquid, the treatment can be performed appropriately at the number of rotations for solidified film formation.

It is preferred in the aspect of the present invention that the substrate treating apparatus further includes a concentration detector configured to detect a concentration of the sublimable substance in the solidified film forming liquid, and that when a detection result of the concentration detector reveals that a variation of the concentration of the sublimable substance in the solidified film forming liquid occurs from the predetermined concentration, the controller determines the number of rotations for liquid film formation based on the relationship stored in the memory unit in accordance with the variation of the concentration.

The controller determines the number of rotations for liquid film formation based on the relationship stored in the memory unit in accordance with the variation in the concentration when the detection result of the concentration detector reveals that the concentration of the sublimable substance in the solidified film forming liquid varies from the predetermined concentration. Consequently, even when treatment is determined inappropriate due to the variation of the concentration in the solidified film forming liquid, the treatment can be performed appropriately at the number of rotations for liquid film formation.

Moreover, it is preferred in the aspect of the present invention that the concentration detector detects a concentration of the sublimable substance in the solidified film forming liquid present at the solidified film forming liquid supplying unit.

This can detect a variation in the concentration before supplying the solidified film forming liquid to the substrate. Accordingly, the number of rotations for solidified film formation can be changed rapidly.

Moreover, it is preferred in the aspect of the present invention that the concentration detector detects a concentration of the sublimable substance in the solidified film forming liquid supplied to the top face of the substrate held by the spin holder.

This can detect a variation in the concentration even if the solidified film forming liquid supplying unit has some abnormality. Consequently, inappropriate treatment caused by the variation in the concentration can surely be prevented.

Moreover, it is preferred in the aspect of the present invention that the substrate treating apparatus further includes an evaporation promoting unit configured to promote evaporation of the solvent from the liquid film of the solidified film forming liquid, and that the controller controls the evaporation promoting unit so as to promote the evaporation of the solvent from the liquid film.

The evaporation promoting unit promotes the evaporation of the solvent from the liquid film. This can shorten time for forming the solidified film.

Moreover, it is preferred in the aspect of the present invention that the substrate treating apparatus further includes a sublimation promoting unit configured to promote sublimation of the solidified film from the substrate, and that the controller controls the sublimation promoting unit so as to promote sublimation of the solidified film from the substrate.

The sublimation promoting unit promotes the sublimation of the solidified film. This can shorten time before a drying treatment.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a plan view schematically illustrating a configuration of a substrate treating apparatus according to a first embodiment of the present invention.

FIG. 2 is a block diagram of the substrate treating apparatus according to the first embodiment.

FIG. 3 illustrates configurations of a treating unit and a solidified film forming liquid generating unit.

FIG. 4 is a graph illustrating measurement examples of a solidified film thickness (liquid film thickness).

FIG. 5 is a schematic view illustrating one example of a concentration calibration curve of cyclohexanone oxime.

FIG. 6 is a schematic view illustrating one example of a rotation number calibration curve of cyclohexanone oxime.

FIG. 7 is a schematic view illustrating one example of a concentration calibration curve of pinacolone oxime.

FIG. 8 is a schematic view illustrating one example of a rotation number calibration curve of pinacolone oxime.

FIG. 9 is a flowchart illustrating one example of substrate treatment.

FIG. 10 is a schematic view illustrating a condition of a substrate where a solidified film forming liquid is supplied.

FIG. 11 is a schematic view illustrating a condition of a substrate in a process of forming a solidified film.

FIG. 12 is a schematic view illustrating a condition of a substrate in a process of forming a solidified film.

FIG. 13 is a schematic view illustrating a condition of a substrate while the solidified film is sublimated.

FIG. 14 is a schematic view illustrating a condition of a substrate where a solidified film is sublimated.

FIG. 15 illustrates configurations of a treating unit and a solidified film forming liquid generating unit of a substrate treating apparatus according to a second embodiment.

FIG. 16 is a block diagram of the substrate treating apparatus 2 according to the second embodiment.

FIG. 17 is a flowchart illustrating one example of substrate treatment.

### DESCRIPTION OF THE PREFERRED EMBODIMENTS

The present invention will be described with reference to the following embodiments.

### First Embodiment

The following describes a first embodiment of the present invention with reference to the drawings.

### 1-1. Outline of Substrate Treating Apparatus

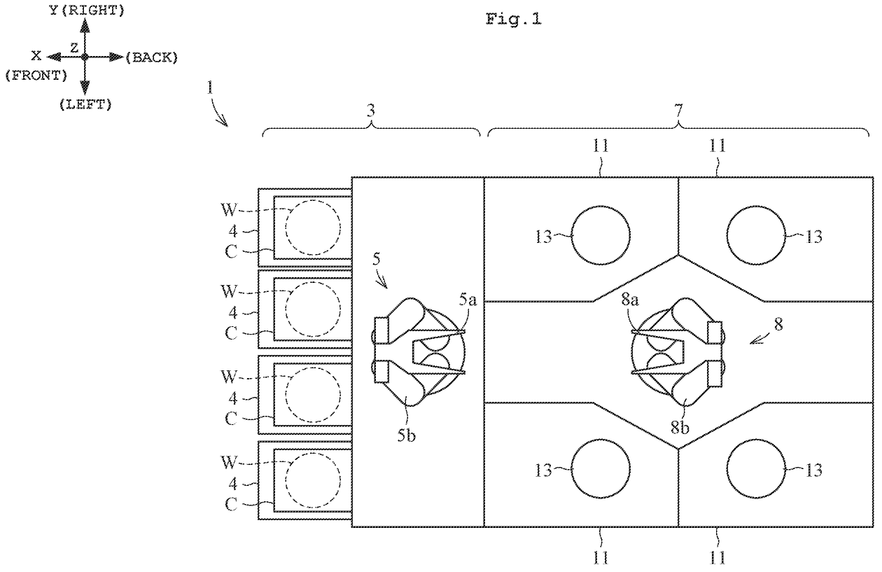

FIG. 1 is a plan view schematically illustrating a configuration of a substrate treating apparatus according to a first embodiment of the present invention.

A substrate treating apparatus 1 performs given treatment on a substrate W. The given treatment includes a drying treatment. Examples of the substrate W to be treated include a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, and a solar cell substrate. The substrate W has a thin flat plate shape in appearance. The substrate W has a substantially circular shape in plan view.

The substrate treating apparatus 1 includes an indexer 3, and a treating block 7. The treating block 7 is connected to the indexer 3. The indexer 3 supplies a substrate W to the treating block 7. The treating block 7 performs treatment on the substrate W supplied from the indexer 3. The indexer 3 collects the treated substrate W from the treating block 7.

In this specification, the direction in which the indexer 3 and the treating block 7 are arranged is referred to as a “front-back direction X” for convenience. The front-back direction X is horizontal. One direction of the front-back direction X from the treating block 7 to the indexer 3 is referred to as a “forward direction”. The direction opposite to the forward direction is referred to as a “rearward direction”. A horizontal direction orthogonal to the front-back direction X is referred to as a “width direction Y”. Moreover, one direction of the width direction Y is referred to as “rightward”, as appropriate. The direction opposite to rightward is referred to as “leftward”. The perpendicular direction relative to the horizontal direction is referred to as a “vertical direction Z”. For reference, the drawings show front, rear, right, left, up, and down, as appropriate.

The indexer 3 includes a plurality of (e.g., four) carrier platforms 4. The carrier platforms 4 each include one carrier C placed thereon. The carrier C accommodates a plurality of substrates W. The carrier C accommodates a substrate W in a horizontal attitude. The carrier C is, for example, a front opening unified pod (FOUP), a standard mechanical interface (SMIF), or an open cassette (OC).

The indexer 3 includes a transport mechanism 5. The transport mechanism 5 is located behind the carrier platforms 4. The transport mechanism 5 transports the substrate W. The transport mechanism 5 is accessible to the carriers C placed on the carrier platforms 4, respectively. The transport mechanism 5 includes a hand 5a and a hand driving unit 5b. The hand 5a supports the substrate W. The hand driving unit 5b is coupled to the hand 5a. The hand driving unit 5b moves the hand 5a. The hand driving unit 5b moves the hand 5a in the front-back direction X, width direction Y, and vertical direction Z, for example. The hand driving unit 5b rotates the hand 5a in a horizontal plane, for example.

The treating block 7 includes a transport mechanism 8. The transport mechanism 8 transports substrates . The substrates W can be delivered between the transport mechanism 5 and the transport mechanism 8. The transport mechanism 8 includes a hand 8a and a hand driving unit 8b. The hand 8a supports the substrate W. The hand driving unit 8b is coupled to the hand 8a. The hand driving unit 8b moves the hand 8a. The hand driving unit 8b moves the hand 8a in the front-back direction X, width direction Y, and vertical direction Z, for example. The hand driving unit 8b rotates the hand 8a in a horizontal plane, for example.

The treating block 7 includes a plurality of treating units 11. The treating units 11 are arranged laterally of the transport mechanism 8. The treating units 11 each perform treatment on a substrate W individually.

The treating unit 11 includes a substrate holder 13. The substrate holder 13 holds a substrate W.

The transport mechanism 8 is accessible to the treating units 11 individually. The transport mechanism 8 can deliver a substrate W on the substrate holder 13. The transport mechanism 8 can take a substrate W from the substrate holder 13.

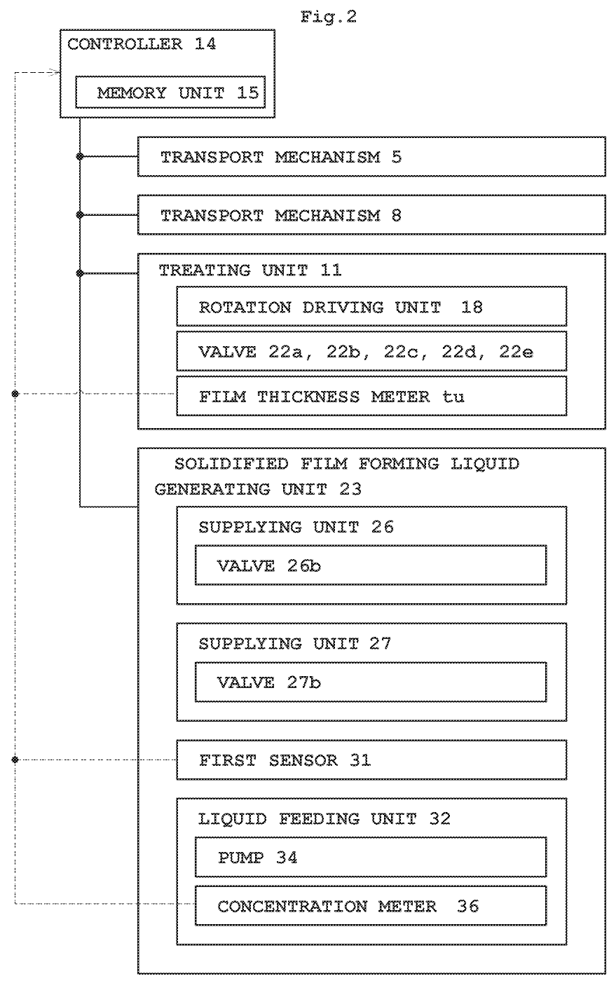

Reference is now made to FIG. 2. FIG. 2 is a block diagram of the substrate treating apparatus according to the first embodiment.

The substrate treating apparatus 1 includes a controller 14. The controller 14 controls the transport mechanisms 5 and 8, and the treating units 11.

The controller 14 is implemented by a central processing unit (CPU) that performs various processing, a random-access memory (RAM) as a workspace of arithmetic processing, and a storage medium such as a fixed disk. The controller 14 contains various types of information stored in a storage medium in advance. The information stored in the controller 14 includes transportation information for controlling the transport mechanisms 5, 8, for example. The information stored in the controller 14 includes processing information for controlling the treating units 11, for example. The processing information is also called recipes. The controller 14 includes a memory unit 15. The memory unit 15 stores recipes in advance. The memory unit 15 stores a plurality of recipes. The recipes include a film thickness of a solidified film to be formed on the substrate W with a solidified film forming liquid. The memory unit 15 stores a relationship in advance, which is to be mentioned later in detail. The relationship is a correlation among a concentration of the solidified film forming liquid, a film thickness of the solidified film as a target to be formed through treatment, and a number of rotations of the substrate W for forming the solidified film. The relationship has a correlation among factors such as the concentration.

The following simply describes one example of operation of the substrate treating apparatus 1 described above.

The indexer 3 supplies a substrate W, prior to treatment, to the treating block 7. Specifically, the transport mechanism 5 delivers the substrates W from the carrier C to the transport mechanism 8 of the treating block 7. The treating block 7 distributes the substrates W from the indexer 3 to the treating unit 11. Specifically, the transport mechanism 8 transports the substrates W from the transport mechanism 5 to the substrate holders 13 of the treating units 11 individually. The treating unit 11 performs treatment on a substrate W held by the substrate holder 13. The treating unit 11 performs a drying treatment, for example, on the substrate W. After the treating unit 11 performs treatment on the substrate W, the treating block 7 returns the substrate W from the treating unit 11 to the indexer 3. Specifically, the transport mechanism 8 transports the substrate W from the substrate holder 13 to the transport mechanism 5. The indexer 3 collects the substrate W from the treating block 7. Specifically, the transport mechanism 5 transports the substrate W from the transport mechanism 8 to the carrier C.

### 1-2 Construction of Treating Unit 11

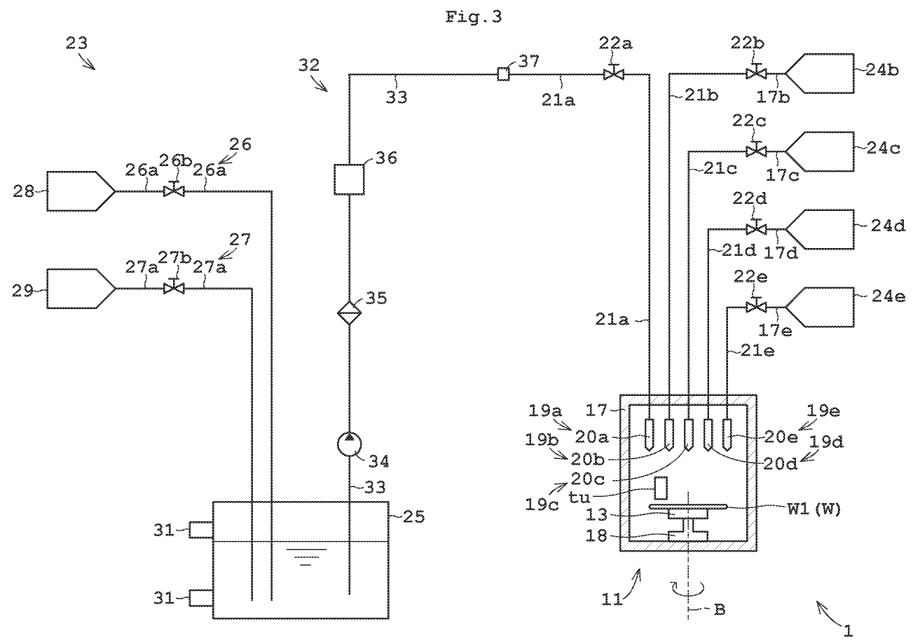

Reference is now made to FIG. 3. FIG. 3 illustrates configurations of the treating unit and the solidified film forming liquid generating unit.

The treating unit 11 is classified as a single-wafer processing unit. That is, the treating units 11 each perform treatment on only one substrate W at one time.

The treating unit 11 includes a casing 17. The casing 17 has a substantial box shape. The substrate W is treated within the casing 17. The interior of the casing 17 is kept at room temperatures in this embodiment. The interior of the casing 17 is kept at normal pressure. Accordingly, the substrate W is treated under an environment of room temperatures and normal pressure.

The treating unit 11 includes a rotation driving unit 18. At least part of the rotation driving unit 18 is arranged inside of the casing 17. The rotation driving unit 18 is connected to the substrate holder 13. The rotation driving unit 18 rotates the substrate holder 13. The substrate W held by the substrate holder 13 rotates integrally with the substrate holder 13. The substrate W rotates in a horizontal plane. The substrate W held by the substrate holder 13 rotates around a rotation axis B. The rotation axis B passes through the center of the substrate W and extends in the vertical direction Z, for example.

The treating unit 11 includes one or more (e.g., five) supplying units 19a, 19b, 19c, 19d, and 19e. The supplying units 19a to 19e each supply a liquid or gas to the substrate W. More specifically, the supplying units 19a to 19e each supply a liquid or gas to the substrates W held by the substrate holder 13. The supplying units 19a to 19e each supply a liquid or gases to a top face W1 of the substrate W held by the substrate holder 13.

Specifically, the supplying unit 19a supplies a solidified film forming liquid. The solidified film forming liquid contains a sublimable substance and a solvent. As described above, the interior of the casing 17 is kept at room temperatures and normal pressure. Accordingly, the solidified film forming liquid is used under an environment of room temperatures. The solidified film forming liquid is used under an environment of normal pressure.

The supplying unit 19b supplies a chemical liquid. The chemical liquid is, for example, an etchant. The chemical liquid includes, for example, at least either hydrofluoric acid (HF) or buffered hydrofluoric acid (BHF).

The supplying unit 19c supplies a rinse liquid. The rinse liquid is, for example, deionized water (DIW).

The supplying unit 19d supplies a replacement solution. The replacement solution is, for example, an organic solvent. The replacement solution is, for example, isopropyl alcohol (IPA).

The supplying unit 19e supplies a first gas. The first gas is, for example, a dry gas. The dry gas has a dew point lower than room temperatures. The dew point is, for example, approximately -76 degrees centigrade. Accordingly, the dry gas does not dew at room temperatures. The first gas is, for example, air, compressed air, inert gas, or nitrogen gas.

The supplying unit 19a includes a nozzle 20a. Likewise, the supplying units 19b to 19e include nozzles 20b to 20e, respectively. The nozzles 20a to 20e are each located inside of the casing 17. The nozzle 20a dispenses the solidified film forming liquid. The nozzle 20b dispenses the chemical liquid. The nozzle 20c dispenses the rinse liquid. The nozzle 20d dispenses the replacement solution. The nozzle 20e dispenses or blows out the first gas.

The nozzles 20a to 20e are each movable between a treating position and a standby position. The treating position is, for example, a position above the substrate W held by the substrate holder 13. The treating position is, for example, a position above the center of the substrate W held by the substrate holder 13. The center of the substrate W intersects the rotation axis B. The standby position is, for example, a position apart from the above of the substrate W held by the substrate holder 13.

The supplying unit 19a includes a pipe 21a. The pipe 21a is connected to the nozzle 20a. Likewise, the supplying units 19b to 19e include pipes 21b to 21e, respectively. The pipes 21b to 21e are connected to the nozzles 20b to 20e, respectively.

The supplying unit 19a includes a valve 22a. The valve 22a is provided on the pipe 21a. When the valve 22a opens, the nozzle 20a dispenses the solidified film forming liquid. When the valve 22a closes, the nozzle 20a does not dispense the solidified film forming liquid. Likewise, the supplying units 19b to 19e include valves 22b to 22e, respectively. The valves 22b to 22e are provided on the pipes 21b to 21e, respectively. The valves 22b to 22e controls supply of the chemical liquid, the rinse liquid, the replacement solution, and the first gas, respectively.

At least part of the pipe 21a may be provided externally of the casing 17. The pipes 21b to 21e may be arranged in the same manner as the pipe 21a. The valve 22a may be provided outside of the casing 17. The valves 22b to 22e may be arranged in the same manner as the valve 22a.

Here, the substrate holder 13 described above corresponds to the “spin holder” in the present invention. The supplying unit 19e and the nozzle e mentioned above correspond to the “sublimation promoting unit” in the present invention.

The treating unit 11 includes a film thickness meter tu in the casing 17.

The film thickness meter tu is located above the substrate holder 13. The film thickness meter tu measures a film thickness of the solidified film formed with the solidified film forming liquid supplied from the supplying unit 19a to the substrate W. It is preferred that the film thickness meter tu is, for example, of a non-contact type using spectral interferometry. In the spectral interferometry, light is emitted toward the substrate W and reflected light is received. The reflected light is multiple reflected light reflected on the surface of the substrate W and the liquid film surface of the solidified film forming liquid, and its intensity changes in accordance with a phase difference between them. Such reflected light indicates a characteristic spectrum depending on the film thickness. The spectral interferometry measures a film thickness by analyzing this spectrum.

The film thickness meter tu is an element necessary for measuring a correlation described later. Accordingly, it may be attached inside of the casing 17 only when necessary, and may be removed from the casing 17 when unnecessary. The film thickness meter tu is an element only necessary for measuring the correlation, and thus is not essential to the present invention. In other words, correlation information, to be described later, may be collected by another apparatus, and may be stored in the substrate treating apparatus 1 for use.

The substrate treating apparatus 1 includes a solidified film forming liquid generating unit 23. The solidified film forming liquid generating unit 23 generates the solidified film forming liquid.

The solidified film forming liquid generating unit 23 is located outside of the casing 17. The solidified film forming liquid generating unit 23 is connected in fluid communication with the supplying unit 19a. The solidified film forming liquid generating unit 23 is connected to the pipe 21a, for example. The solidified film forming liquid generating unit 23 feeds the solidified film forming liquid to the supplying unit 19a.

The supplying unit 19b is connected in fluid communication with a chemical liquid supplying source 24b. The chemical liquid supplying source 24b is connected to the pipe 21b, for example. The chemical liquid supplying source 24b feeds a chemical liquid to the supplying unit 19b.

The supplying unit 19c is connected in fluid communication with a rinse liquid supplying source 24c. The rinse liquid supplying source 24c is connected to the pipe 21c, for example. The rinse liquid supplying source 24c feeds a rinse liquid to the supplying unit 19c.

The supplying unit 19d is connected in fluid communication with a replacement solution supplying source 24d. The replacement solution supplying source 24d is connected to the pipe 21d, for example. The replacement solution supplying source 24d feeds a replacement solution to the supplying unit 19d.

The supplying unit 19e is connected in fluid communication with a first gas supplying source 24e. The first gas supplying source 24e is connected to the pipe 21e, for example. The first gas supplying source 24e feeds a first gas to the supplying unit 19e.

The solidified film forming liquid generating unit 23 mentioned above may feed the solidified film forming liquid to a plurality of treating units 11. Alternatively, the solidified film forming liquid generating unit 23 may feed the solidified film forming liquid to only one treating unit 11. The same is applicable to the chemical liquid supplying source 24b, the rinse liquid supplying source 24c, the replacement solution supplying source 24d, and the first gas supplying source 24e.

Reference is now made to FIG. 2. The controller 14 controls the rotation driving unit 18, and the valves 22a to 22e. The controller 14 obtains detection results of the film thickness meter tu.

### 1-3. Solidified Film Forming Liquid

The following describes a solidified film forming liquid generated by the solidified film forming liquid generating unit 23. The solidified film forming liquid contains a sublimable substance and a solvent. The solidified film forming liquid constitutes only a sublimable substance and a solvent, for example.

The sublimable substance has sublimability. “Sublimable” means a property where a single substance, a chemical compound or a mixture changes its phase from a solid phase to a gas phase or from a gas phase to a solid phase without passing through a liquid phase.

The sublimable substance contains, for example, at least one selected from the following chemical compounds S1 to S4.
Chemical compound S1: pinacolone oxime
Chemical compound S2: acetophenone oxime
Chemical compound S3: cyclohexanone oxime
Chemical compound S4: 4-tert butylphenol

The sublimable substance consists of, for example, at least one selected from the chemical compounds S1 to S4. In other words, the sublimable substance is one selected from the chemical compounds S1 to S4.

The solvent is liquid at room temperatures. The solvent dissolves the sublimable substance. Accordingly, the sublimable substance in the solidified film forming liquid is dissolved in the solvent. That is, the solidified film forming liquid contains the solvent and the sublimable substance dissolved in the solvent. The sublimable substance corresponds to a solute in the solidified film forming liquid.

The solvent has relatively high vapor pressure at room temperatures. For example, it is preferred that the vapor pressure of the solvent at room temperatures is higher than the vapor pressure of the sublimable substance at room temperatures. The solvent is, for example, an organic solvent. The solvent is, for example, alcohol.

The solvent contains, for example, at least one selected from the following chemical compounds Q1 to Q10.
Chemical compound Q1: isopropyl alcohol (IPA)
Chemical compound Q2: acetone
Chemical compound Q3: methanol
Chemical compound Q4: ethanol
Chemical compound Q5: tert-buthanol
Chemical compound Q6: 1-propanol
Chemical compound Q7: isobutanol
Chemical compound Q8: 1-ethoxy-2-propanol
Chemical compound Q9: 1-buthanol
Chemical compound Q10: propyleneglycol monomethyl ether acetate.

A mass of the sublimable substance contained in the solidified film forming liquid is smaller than a mass of the solvent contained in the solidified film forming liquid. A concentration (wt%) of the solidified film forming liquid in the present specification is given by dividing the mass of the sublimable substance by the mass of the solidified film forming liquid times 100. The mass of the solidified film forming liquid is given by adding the mass of the solvent to the mass of the sublimable substance. It is preferred that the concentration (wt%) falls within a range of one or more to 25 or less.

### 1-4. Construction of Solidified Film Forming Liquid Generating Unit 23

Reference is made to FIG. 3. The solidified film forming liquid generating unit 23 generates the solidified film forming liquid.

The solidified film forming liquid generating unit 23 includes a tank 25. The tank 25 is connected in fluid communication with the supplying unit 19a. The tank 25 is connected in fluid communication with the nozzle 20a. In the present embodiment, the solidified film forming liquid generating unit 23 generates the solidified film forming liquid in the tank 25. The solidified film forming liquid is generated under an environment of room temperatures. The solidified film forming liquid is generated under an environment of normal pressure.

The solidified film forming liquid generating unit 23 stores the generated solidified film forming liquid in the tank 25. The solidified film forming liquid is kept under an environment of room temperatures. The solidified film forming liquid is kept under an environment of normal pressure.

The solidified film forming liquid generating unit 23 includes a supplying unit 26 and a supplying unit 27. The supplying unit 26 supplies the sublimable substance to the tank 25. The supplying unit 27 supplies the solvent to the tank 25. The sublimable substance and the solvent are mixed within the tank 25. Thereby, the solidified film forming liquid containing the sublimable substance and the solvent is generated.

The supplying unit 26 is in fluid communication with the tank 25. The supplying unit 26 is also in fluid communication with a sublimable substance supplying source 28. The sublimable substance supplying source 28 feeds the sublimable substance to the supplying unit 26.

The supplying unit 26 includes a pipe 26a and a valve 26b, for example. The pipe 26a has a first end connected in fluid communication with the tank 25, and a second end connected in fluid communication with the sublimable substance supplying source 28. The valve 26b is provided on the pipe 26a. The valve 26b opens and closes, whereby the supplying unit 26 is switched between a condition of supplying the sublimable substance to the tank 25 and a condition of not supplying the sublimable substance to the tank 25.

The supplying unit 27 is in fluid communication with the tank 25. The supplying unit 27 is also in fluid communication with a solvent supplying source 29. The solvent supplying source 29 feeds the solvent to the supplying unit 27.

The supplying unit 27 includes a pipe 27a and a valve 27b, for example. The pipe 27a has a first end connected in fluid communication with the tank 25, and a second end connected in fluid communication with the solvent supplying source 29. The valve 27b is provided on the pipe 27a. The valve 27b opens and closes, whereby the supplying unit 27 is switched between a condition of supplying the solvent to the tank 25 and a condition of not supplying the solvent to the tank 25.

The solidified film forming liquid generating unit 23 includes at least one or more (e.g., two) first sensors 31. The first sensor 31 detects an amount of the solidified film forming liquid stored in the tank 25. The first sensor 31 is attached to the tank 25, for example. The first sensor 31 detects a height position of a liquid level of the solidified film forming liquid stored in the tank 25, for example. The first sensor 31 is, for example, a liquid level sensor.

The solidified film forming liquid generating unit 23 includes a liquid feeding unit 32. The liquid feeding unit 32 feeds the solidified film forming liquid from the tank 25 to the supplying unit 19a.

The liquid feeding unit 32 includes a pipe 33, a pump 34, a filter 35, a concentration meter 36, and a joint 37, for example. The pipe 33 is connected in fluid communication with the third tank 25. The pump 34 is provided on the pipe 33. The filter 35 is provided on the pipe 33. The joint 37 is connected to the pipe 33. The joint 37 is also connected to the pipe 21a. The pipes 33 and 21a are connected to each other via the joint 37.

The pump 34 feeds the solidified film forming liquid from the tank 25 to the pipe 21a via the pipe 21a and the joint 37. Thereby, the pump 34 feeds the solidified film forming liquid from the tank 25 to the supplying unit 19a. The filter 35 filters the solidified film forming liquid flowing in the pipe 21a. The filter 35 removes foreign substances from the solidified film forming liquid. The concentration meter 36 measures a concentration of the solidified film forming liquid flowing in the pipe 21a. The concentration meter 36 measures a concentration of the sublimable substance in the solidified film forming liquid. The concentration meter 36 is a concentration meter of a non-contact type. The concentration meter 36 emits light having given intensity, and calculates the concentration in accordance with the intensity of light having passed through the solidified film forming liquid. The concentration meter 36 measures a concentration, which is a proportion of the mass of the sublimable substance in the solidified film forming liquid, in accordance with absorbance, for example.

Here, the concentration meter 36 described above corresponds to the “concentration detector” in the present invention.

Reference is made to FIG. 2. The controller 14 controls the solidified film forming liquid generating unit 23. The controller 14 is communicably and electrically connected to the solidified film forming liquid generating unit 23. The controller 14 controls the supplying units 26 and 27, and the liquid feeding unit 32. The controller 14 controls the valves 26b and 27b, and the pump 34. The controller 14 obtains detection results of the first sensor 31. The controller 14 obtains detection results of the concentration meter 36.

The controller 14 stores solidified film forming liquid generating information used for controlling the solidified film forming liquid generating unit 23. The solidified film forming liquid generating information is stored in advance in a storage medium of the controller 14. The solidified film forming liquid generating information contains concentrations of the sublimable substance in the solidified film forming liquid.

The controller 14 refers to the memory unit 15, as necessary. The memory unit 15 stores in advance a relationship among a concentration of the sublimable substance in the solidified film forming liquid, a target solidified film thickness as a desired film thickness of the solidified film formed on the substrate W with the solidified film forming liquid, and a number of rotations for solidified film formation as a number of rotations of the substrate for forming the solidified film of the target film thickness when the concentration of the solidified film forming liquid is a predetermined concentration.

Here, the nozzle 20a described above corresponds to the “solidified film forming liquid supplying unit” in the present invention. The target film thickness described above corresponds to the “target solidified film thickness” in the present invention.

### 2-1. Example of Film Thickness Measurement

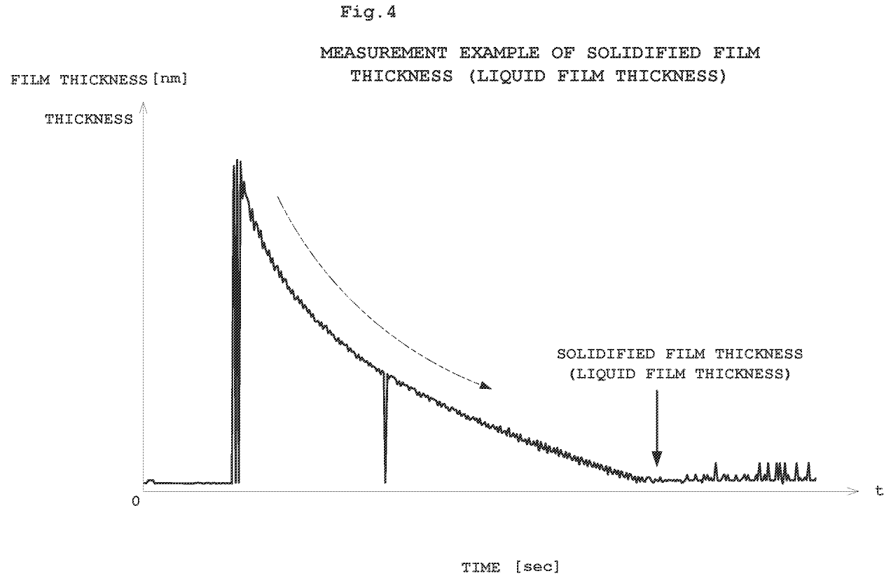

Reference is now made to FIG. 4. FIG. 4 is a graph illustrating measurement examples of the solidified film thickness (liquid film thickness).

FIG. 4 is a measurement example using a solidified film forming liquid in which a sublimable substance is pinacolone oxime and a solvent is isopropyl alcohol.

Specifically, the solidified film forming liquid described above is supplied to the substrate W and the substrate W is rotated at a given rotation speed. At this time, the film thickness meter tu continuously measures a film thickness of the liquid film of the solidified film forming liquid supplied to the top face of the substrate W. The change of the film thickness is illustrated in a graph. The solidified film forming liquid supplied to the substrate W and covering the entire top face of the substrate W has a constant liquid film thickness. The solidified film forming liquid flows toward an outer circumference of the substrate W as the substrate W rotates, and scatters around. Accordingly, as illustrated by chain double-dashed line with an arrow in FIG. 4, the liquid film thickness decreases progressively with time from when the measurement of the liquid film thickness starts.

In this example, the sublimable substance starts to be deposited immediately before a position indicated by a down-pointing arrow. This reduces flowability of the solidified film forming liquid, leading to a substantial constant value of the film thickness as a measured value. Then, the deposition of the sublimable substance progresses and the film entirely becomes a solidified film. Accordingly, the film thickness at the time indicated by a position of the down-pointing arrow is the film thickness of the solidified film formed with the solidified film forming liquid. The film thickness at the time indicated by the down-pointing arrow is also a boundary between a light-permeable liquid film in which reflected light returns from the top face of the substrate W and a light-impermeable solid film in which reflected light does not return from the top face of the substrate W. Therefore, the film thickness at this time is also the liquid film thickness of the solidified film forming liquid. That is because the time point at which the sublimable substance is deposited is also the state of the solidified film forming liquid.

### 2-2. Concentration Calibration Curve of Cyclohexanone Oxime

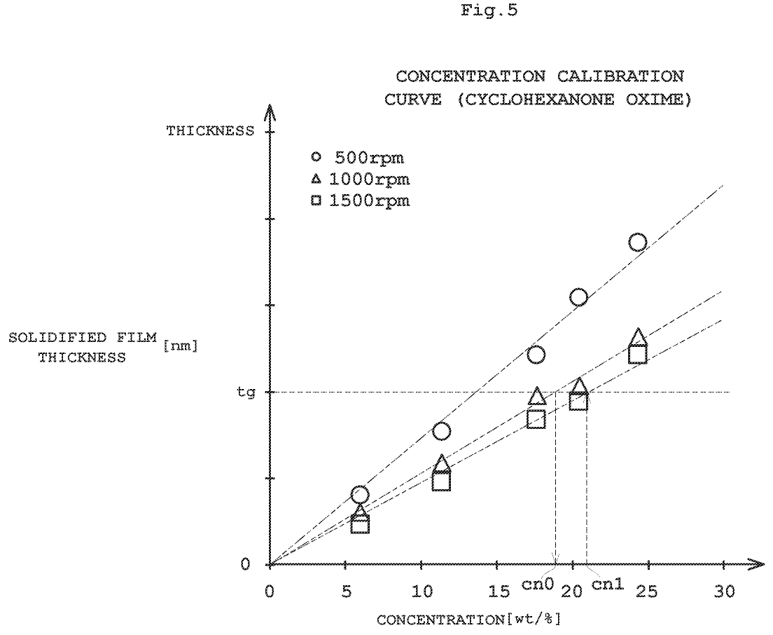

Reference is now made to FIG. 5. FIG. 5 is a schematic view illustrating one example of a concentration calibration curve of cyclohexanone oxime.

The following describes a concentration calibration curve when cyclohexanone oxime is adopted as a sublimable substance in a solidified film forming liquid. The concentration calibration curve is obtained for every number of rotations of the substrate W rotated by the rotation driving unit 18 regarding a relationship between a concentration of the sublimable substance in the solidified film forming liquid and a film thickness of the solidified film formed with the solidified film forming liquid. In other words, the relationship is a correlation among a concentration of the sublimable substance in the solidified film forming liquid, a film thickness of the solidified film formed with the solidified film forming liquid, and a number of rotations of the substrate W. Moreover, the concentration calibration curve represents a change in solidified film thickness with respect to a variation in the concentration.

For example, a number of rotations of the substrate W is set to 500 rpm, 1000 rpm, and 1500 rpm, and a film thickness of the solidified film formed is measured when a concentration is changed at each number of rotations. FIG. 5 illustrates an approximating line by chain double-dashed lines. In this case, the approximating line is expressed by the following equation (1): Here, symbols in the equation (1) mean the following: y is a film thickness of the solidified film (nm), a is a gradient (nm/wt%), and x is a concentration of the sublimable substance in the solidified film forming liquid (wt%).

$$y = a x$$

The concentration calibration curve is used as under.

For example, when a certain film thickness of a solidified film is set as a target film thickness tg, and the number of rotations of the substrate W rotated by the rotation driving unit 18 is set to 1000 rpm, draw a horizontal line from the target film thickness on a vertical axis, and then draw a perpendicular line from an intersection of the horizontal line and a chain double-dashed line connecting triangles in FIG. 5. A concentration cn0 at a position where the perpendicular line intersects with the horizontal axis is the concentration of the sublimable substance necessary to obtain the target film thickness at a predetermined number of rotations of 1000 rpm. It is revealed from the concentration calibration curve that a gradient of the approximate equation becomes large and sensitivity of the concentration variation in the solidified film forming liquid becomes high as the number of rotations is small.

Here, it is assumed that the concentration of the solidified film forming liquid increases from a concentration cn0 to a concentration cn1. If FIG. 5 is used, a perpendicular line is drawn from the concentration cn1 to obtain a number of rotations of 1500 rpm close to an intersection of the horizontal line of the target film thickness tg and the perpendicular line of the concentration cn1. Then, using the number of rotations of 1500 rpm can obtain a target film thickness tg at the concentration cn1. The number of rotations can be similarly obtained with the equation (1) from a gradient a when a film thickness y is fixed while a concentration x is changed.

The approximate equation of the equation (1) is previously stored in the memory unit 15, and the controller 14 operates the solidified film forming liquid generating unit 23 to generate and supply a solidified film forming liquid having the necessary concentration. This can form a solidified film of the target film thickness at a predetermined number of rotations. If the concentration varies, the number of rotations is adjusted in such a manner as above.

### 2-3. Rotation Number Calibration Curve of Cyclohexanone Oxime

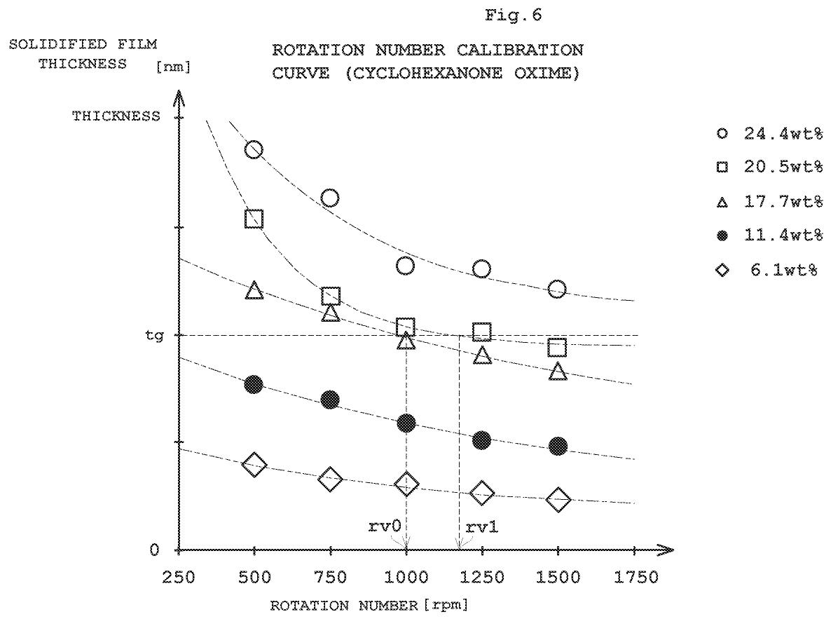

Reference is now made to FIG. 6. FIG. 6 is a schematic view illustrating one example of a rotation number calibration curve of cyclohexanone oxime.

The following describes a rotation number calibration curve when cyclohexanone oxime is adopted as a sublimable substance in a solidified film forming liquid. The rotation number calibration curve is obtained for every concentration of the sublimable substance in the solidified film forming liquid regarding a relationship between the number of rotations of the substrate W and the solidified film thickness of the solidified film forming liquid. In other words, the relationship is a correlation among a concentration of the sublimable substance in the solidified film forming liquid, a film thickness of the solidified film formed with the solidified film forming liquid, and a number of rotations of the substrate W. Moreover, the rotation number calibration curve represents a change in solidified film thickness with respect to a change in the number of rotations.

For example, a concentration is set to 24.4 wt%, 20.5 wt%, 17.7 wt%, 11.4 wt%, and 6.1 wt%, and a film thickness of the solidified film formed is measured when a number of rotations is changed at each concentration of the solidified film forming liquid. FIG. 6 illustrates an approximating line by chain double-dashed lines. In this case, the approximating line is expressed by the following equation (2). Here, symbols in the equation (2) mean the following: y is a film thickness of the solidified film (nm), y₀ is a coefficient (nm), a is a coefficient (nm), b is a coefficient (rpm), and x is a number of rotations of the substrate W (rpm)].

$$y = {y}_{0} + a {e}^{- x / b}$$

The rotation number calibration curve is used as under.

For example, when a certain film thickness of a solidified film is set as a target film thickness tg, and the solidified film is formed using a solidified film forming liquid of 17.7 wt% (concentration cn0), draw horizontal line a from the target film thickness tg on a vertical axis, and then draw a perpendicular line from an intersection of the horizontal line and a chain double-dashed line connecting triangles in FIG. 6A number of rotations rv0 at a position where the perpendicular line intersects with the horizontal axis is the number of rotations necessary to obtain the target film thickness with a solidified film forming liquid of 17.7 wt%.

Here, it is assumed that the concentration of the solidified film forming liquid increases from a concentration of 17.7 wt% (cn0) to a concentration of 20.5 wt% (concentration cn1). If FIG. 6 is used, a perpendicular line is drawn from an intersection of a horizontal line of the target film thickness tg and the approximating line of a concentration of 20.5 wt% (concentration cn1) to obtain a number of rotations rv1 where the perpendicular line intersects. Then using the number of rotations rv1 can obtain a target film thickness tg at the concentration cn1. The number of rotations x can be similarly obtained with the equation (2) from a coefficient y₀, a coefficient a, and a coefficient b when a film thickness y is fixed while a concentration is changed.

The approximate equation of the equation (2) is previously stored in the memory unit 15, and the controller 14 operates the rotation driving unit 18 to generate and supply a solidified film forming liquid having the necessary concentration. The substrate W is rotated at a necessary number of rotations. This can form a solidified film of the target film thickness at a predetermined number of rotations. If the concentration varies, the number of rotations is adjusted in such a manner as above.

### 2-4. Concentration Calibration Curve of Pinacolone Oxime

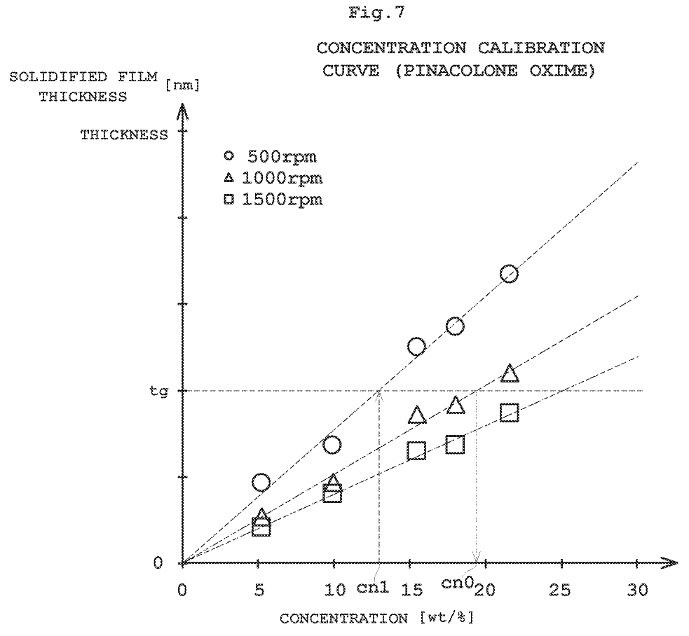

Reference is made to FIG. 7. FIG. 7 is a schematic view illustrating one example of a concentration calibration curve of pinacolone oxime.

The concentration calibration curve differs from that described in the example <2-2. Concentration calibration curve of cyclohexanone oxime> in sublimable substance. The approximate equation herein is equal to the expression (1) described above.

If the concentration calibration curve is used, when the concentration decreases from the concentration cn0 to the concentration cn1 as described in the example <2-2. Concentration calibration curve of cyclohexanone oxime>, a target film thickness tg is obtained by changing the number of rotations from 1000 rpm to 500 rpm, for example.

Here, the concentration calibration curve and the rotation number calibration curve described above correspond to the “relationship” in the present invention.

### 2-5. Rotation Number Calibration Curve of Pinacolone Oxime

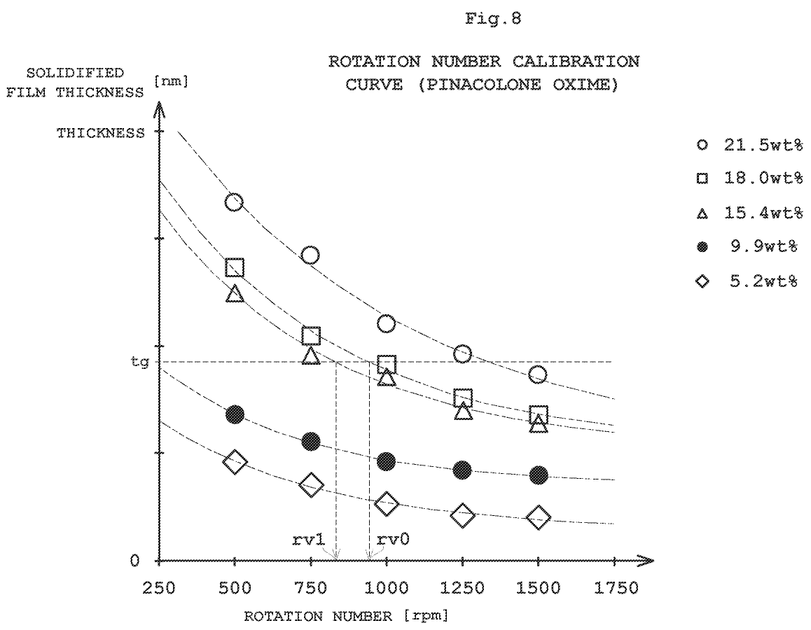

Reference is made to FIG. 8. FIG. 8 is a schematic view illustrating one example of a rotation number calibration curve of pinacolone oxime.

The rotation number calibration curve differs from that described in the example <2-3. Rotation number calibration curve of cyclohexanone oxime> in sublimable substance. The approximate equation herein is equal to the expression (2) described above.

If the rotation number calibration curve is used, when the concentration of the solidified film forming liquid decreases from 18.0 wt% (concentration cn0) to 15.4 wt% (concentration cn1) as described in the example <2-3. Rotation number calibration curve of cyclohexanone oxime>, a target film thickness tg is obtained by reducing the number of rotations from rv0 to rv1, for example.

### 3-1. Operational Example

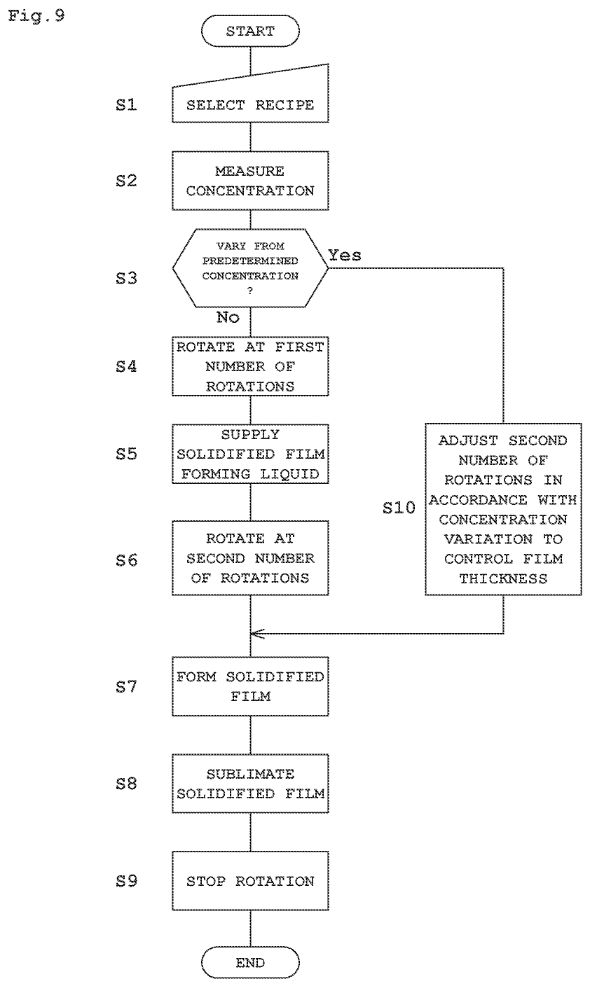

FIG. 9 is a flowchart illustrating one example of substrate treatment. Although not described in this flowchart, generation treatment executed by the solidified film forming liquid generating unit 23 is performed in parallel. At this time, the first sensor 31 detects an amount of the solidified film forming liquid stored in the tank 25. The controller 14 monitors detection results of the first sensor 31. The controller 14 starts and stops a solidified film forming liquid generating step in accordance with detection results of the first sensor 31.

In the following description, it is assumed that a chemical liquid treatment step, a rinse liquid supplying step, and a replacement solution supplying step have already been performed. The following simply describes these treatment steps.

### Chemical Liquid Treatment Step

A substrate W to be treated is held by the substrate holder 13. The rotation driving unit 18 rotates the substrate holder 13. The controller 14 supplies a chemical liquid from the supplying unit 19b to the substrate W. Thereby, a native oxide is removed from the substrate W, for example.

### Rinse Liquid Supplying Step

The controller 14 supplies a rinse liquid from the supplying unit 19c to the substrate W. Thereby, a chemical liquid is removed from the substrate W, for example.

### Replacement Solution Supplying Step

The controller 14 supplies a replacement solution from the supplying unit 19d to the substrate W. The replacement solution removes the rinse liquid from the substrate W. This achieves replacement of the rinse liquid with the replacement solution on the substrate W.

Then, subsequent to the replacement solution supplying step described above, a solidified film forming liquid supplying step is performed.

The present embodiment describes a case where a solidified film is formed in accordance with the “relationship represented by the rotation number calibration curve” illustrated in FIGS. 6 and 8. That is, the substrate W is rotated at a number of rotations in correspondence to the target film thickness in accordance with a rotation number calibration curve for a predetermined concentration when a solidified film is formed with a solidified film forming liquid having the predetermined concentration.

### Step S1

An operator of the substrate treating apparatus 1 selects a recipe. The step S1 may be performed before the chemical liquid treatment step, the rinse liquid supplying step, and the replacement solution supplying step described above.

Thereby, the recipe containing a target film thickness of the solidified film to be formed is selected. The recipe is selected via an instruction unit, not shown, connected to the controller 14. The instruction unit is composed of a keyboard, a pointing device, and a display unit, for example. The recipe contains, for example, the target film thickness of the solidified film, a concentration of a solidified film forming liquid, a first number of rotations, duration of time of the first number of rotations, a second number of rotations, and duration of time of the second number of rotations. The controller 14 reads out an approximate equation from the memory unit 15. The approximate equation is the equation (1) or the equation (2) based on the sublimable substance.

The controller 14 operates the valves 26b and 27b to obtain a concentration of the solidified film forming liquid specified in the recipe through controlling the solidified film forming liquid generating unit 23. Thereby, the solidified film forming liquid having the concentration specified in the recipe is generated in the tank 25. Strictly speaking, however, the concentration does not match the specified concentration, and a certain difference may generate.

Here, the target film thickness of the solidified film described above corresponds to the “target solidified film thickness” and the “target liquid film thickness” in the present invention.

### Step S2

A concentration of the solidified film forming liquid that is generated in the solidified film forming liquid generating unit 23 is measured. Specifically, the valve 22a is opened and the pump 34 is operated, and a concentration of the solidified film forming liquid fed from the tank 25 into the pipe 33 is measured by the concentration meter 36.

### Step S3

The controller 14 receives the measured concentration from the concentration meter 36. The controller 14 compares the predetermined concentration of the solidified film forming liquid in the recipe to the concentration received from the concentration meter 36. Procedure is divided depending on the result.

Specifically, if the concentration received from the concentration meter 36 does not vary from the predetermined concentration, the procedure proceeds to a step S6. On the other hand, if the concentration received from the concentration meter 36 varies from the predetermined concentration, the procedure proceeds to a step S7.

Here, it is firstly assumed that there is no variation as a result of the comparison in the step S3.

### Step S4

The controller 14 rotates the rotation driving unit 18 at a first number of rotations in accordance with the recipe. This rotates the substrate W over duration of time at the first number of rotations.

### Step S5

The solidified film forming liquid is supplied from the supplying unit 19a to the vicinity of a rotation center of the substrate W. The solidified film forming liquid supplied to the substrate W spreads from the vicinity of the center toward the periphery edge of the substrate W to coat the entire top face of the substrate W. The controller 14 stops the pump 34 and closes the valve 22a. This stops supply of the solidified film forming liquid from the supplying unit 19a.

The first number of rotations when the solidified film forming liquid is supplied is smaller than a second number of rotations mentioned later. Accordingly, scattering of the solidified film forming liquid can be suppressed compared with the case of high-speed rotation from the beginning, leading to suppressed consumption of the solidified film forming liquid.

The steps S2 to S4 described above are executed in a relatively short period of time. Alternatively, the steps S2 to S4 are executed at substantially the same timing. Alternatively, the solidified film forming liquid may be supplied to the substrate W after the substrate W starts its rotation at the first number of rotations so that the step S4 is executed after the step S5.

The steps S4 and S5 correspond to the “entire surface coating step” in the present invention.

### Step S6

The controller 14 rotates the rotation driving unit 18 at a second number of rotations (e.g., 1000 rpm) in accordance with the recipe. The substrate W is rotated over duration of time at the second number of rotations. The second number of rotations is larger than a second number of rotations mentioned later. In other words, the first number of rotations is smaller than the second number of rotations. Thereby, part of the solidified film forming liquid covering the entire top face of the substrate W is scattered off by a centrifugal force, and the thickness of the liquid film of the solidified film forming liquid on the top face of the substrate W is adjusted. After the duration of time elapses, the controller 14 stops the rotation driving unit 18. Thereby, the substrate W rests.

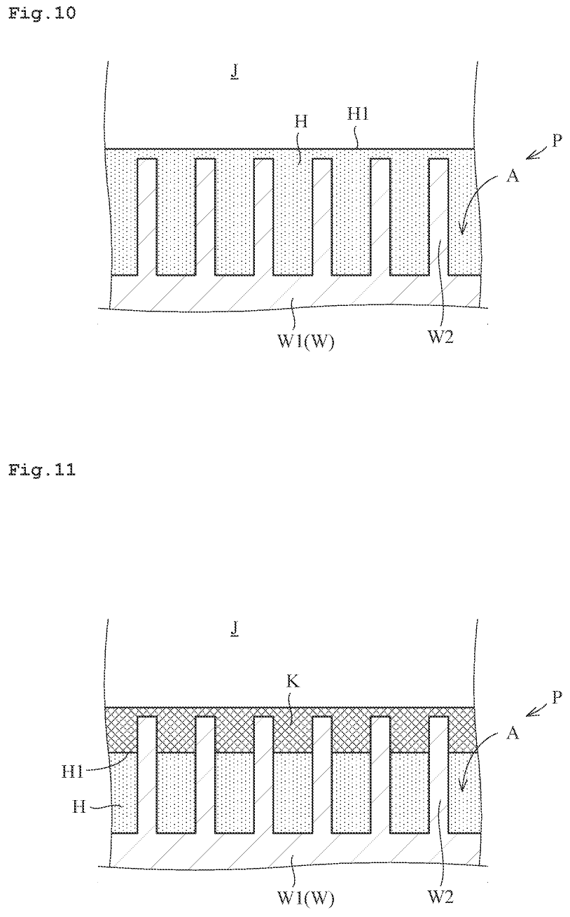

Reference is now made to FIG. 10. FIG. 10 is a schematic view illustrating a condition of the substrate where a solidified film forming liquid is supplied.

The pattern P is formed on the top face W1 of the substrate W. The pattern P includes projections W2 and recesses A. The projections W2 are a component forming part of the substrate W. The projections W2 are each formed with a silicon oxide (SiO₂) film, a silicon nitride (SiN) film, or a polysilicon film, for example. The projections W2 project upward. The recess A is laterally adjacent to the projection W2. The recess A is a space. The recess A is opened upward. The projection W2 corresponds to a wall defining the recess A.

The solidified film forming liquid on the substrate W forms a liquid film H. The liquid film H of the solidified film forming liquid is positioned on the top face W1 of the substrate W. The liquid film H covers the top face W1 of the substrate W. The liquid film H has an upper face H1. The upper face H1 is positioned higher in level than the entire of the pattern P. The pattern P is entirely immersed in the liquid film H. The upper face H1 is positioned higher in level than the entire of the projections W2. The projections W2 are entirely immersed in the liquid film H. The recesses A are filled with the liquid film H. The recesses A are entirely filled only with the liquid film H. Here, the replacement solution has already been removed from the top face W1 of the substrate W by the solidified film forming liquid. Consequently, there is no replacement solution on the top face W1 of the substrate W. No replacement solution remains in the recesses A. Gases J exist above the liquid film H. The gases J contact the upper face H1. The upper face H1 corresponds to a gas-liquid interface between the liquid film H and the gases J.

### Step S7

The controller 14 operates the rotation driving unit 18 to rotate the substrate W at a predetermined number of rotations. Thereby, the solvent is evaporated from the solidified film forming liquid on the substrate W. That is, the solvent is evaporated from the liquid film H. This changes the solvent to gases. Here, the solvent has relatively high vapor pressure. Accordingly, the solvent is easily evaporated.

Here, the step S7 corresponds to the “solidified film forming step” in the present invention. The rotation driving unit 18 corresponds to the “evaporation promoting unit” in the present invention.

Reference is now made to FIG. 11. FIG. 11 is a schematic view illustrating a condition of the substrate in a process of forming a solidified film.

As the solvent evaporates from the liquid film H, the liquid film H gradually changes into a solidified film K.

Specifically, the solvent is removed from the liquid film H with evaporation of the solvent, and the solvent contained in the liquid film H decreases. The concentration of the sublimable substance in the liquid film H increases, and the sublimable substance is deposited on the substrate W. That is, the sublimable substance is changed to solid from the solute of the solidified film forming liquid forming the liquid film H. As a result, the solidified film K is formed on the substrate W. The solidified film K is formed on the top face W1 of the substrate W. The solidified film K contains the sublimable substance. The solidified film K contains the sublimable substance in a solid phase. The solidified film K does not contain the solvent. The solidified film K is solid.

The liquid film H gradually decreases. The solidified film K gradually increases. Firstly, an upper part of the liquid film H changes to the solidified film K. The remaining liquid film H is positioned below the solidified film K. The height position of the upper face H1 of the liquid film H is gradually lowered. The solidified film K covers the upper face H1 of the liquid film H.

After the solidified film K covers the upper face H1 of the liquid film H, the liquid film H does not contact the gases J. The liquid film H is covered with the solidified film K, whereby a gas-liquid interface between the liquid film H and the gases J disappears. The liquid film H contacts the solidified film K. The gases J contact the solidified film K. Accordingly, the liquid film H is reduced in the solidified film forming step without any significant force applied to the projections W2. The solvent is removed from the substrate W without any significant force applied to the projections W2.

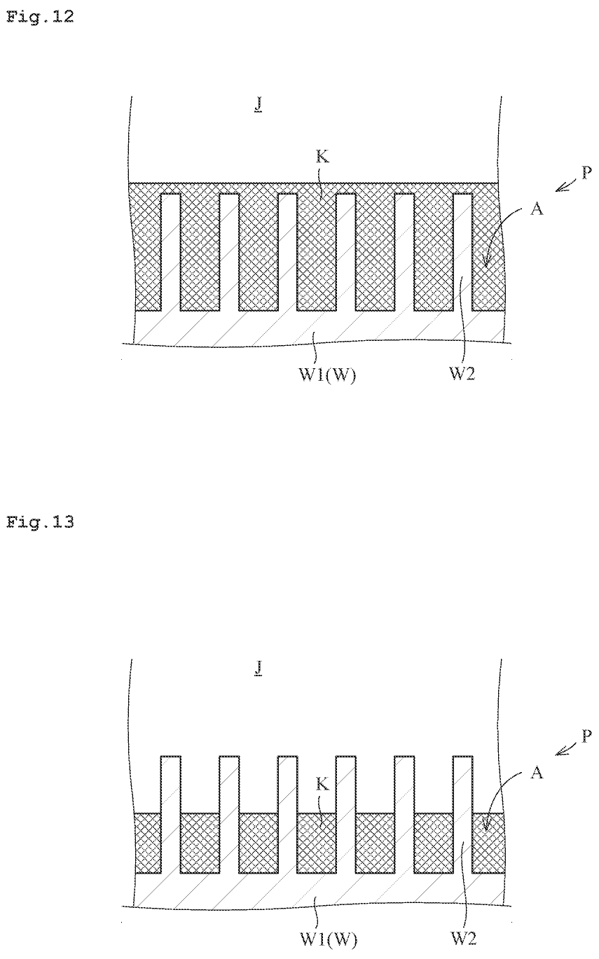

Reference is made to FIG. 12. FIG. 12 is a schematic view illustrating a condition of the substrate in a process of forming the solidified film.

Finally, the liquid film H entirely disappears from the substrate W. There exists no liquid on the top face W1 of the substrate W. The liquid film H does not remain in the recesses A after the solidified film forming step. After the solidified film is formed, no liquid exists in the recesses A. The recesses A are filled with the solidified film K. The recesses A are entirely filled only with the solidified film K. The pattern P contacts the solidified film K. The pattern P does not contact any liquid. The projections W2 contact the solidified film K. The projections W2 do not contact any liquid.

### Step S8

In the step S8, the solidified film K sublimates. The controller 14 supplies a first gas from the supplying unit 19e to the top face W1 of the substrate W. Thereby, the solidified film K sublimates. In other words, the solidified film K changes to gas without being a liquid. Such sublimation of the solidified film K causes the solidified film K to be removed from the substrate W. Then, the supplying unit 19e stops supply of the first gas to the solidified film K.

Here, the step S8 corresponds to the “sublimating step” in the present invention.

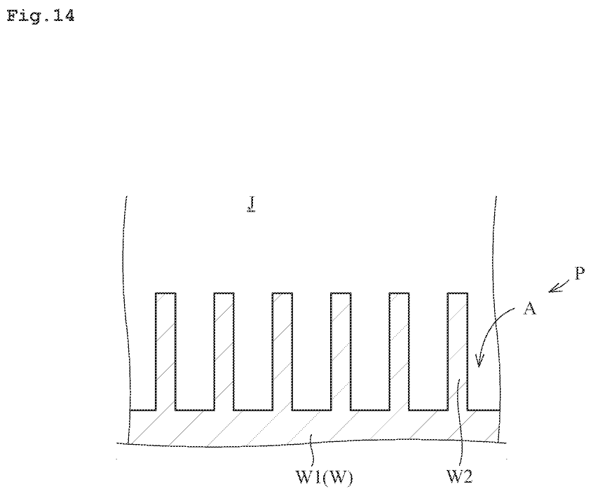

Reference is now made to FIGS. 13 and 14. FIG. 13 is a schematic view illustrating a condition of the substrate while the solidified film is sublimated. FIG. 14 is a schematic view illustrating a condition of the substrate where the solidified film is sublimated.

As illustrated in FIG. 13, the solidified film K gradually decreases as the solidified film K sublimates. The gases J enter the recesses A as the solidified film K sublimates. When the solidified film K sublimates, the solidified film K does not change to liquid. Accordingly, there exists no liquid on the top face W1 of the substrate W in the sublimating step. No liquid exists in the recesses A. The pattern P does not contact any liquid. The projections W2 do not contact any liquid. The solidified film K is removed from the top face W1 of the substrate W without any significant force applied to the projections W2.

Finally, as illustrated in FIG. 14, the solidified film K disappears from the top face W1 of the substrate W. The recesses A are filled with the gases J. The recesses A are entirely filled only with the gases J. There exists no liquid on the top face W1 of the substrate W. The substrate W is dried completely.

### Step S9

The controller 14 operates the rotation driving unit 18 to stop rotation of the substrate holder 13. The substrate W held by the substrate holder 13 stops rotation and rests. The treating unit 11 completes treatment on the substrate W.

The following describes a treatment example in the case where a variation of the concentration received from the concentration meter 36 occurs from the predetermined concentration specified in the recipe through comparison in the step S3 described above.

### Step S10

The controller 14 controls the number of rotations in accordance with the approximate equation. For example, in the equation (2), a film thickness y of a solidified film is fixed at the target film thickness, and a concentration is set at the concentration received from the concentration meter 36. The concentration determines a coefficient y₀, a coefficient a, and a coefficient b. The controller 14 calculates a number of rotations x from the equation (2) in such a manner as above. The controller 14 operates the rotation driving unit 18 to achieve the calculated number of rotations x.

If a concentration falls out of the given value as above, when the rotation driving unit 18 is operated at a number of rotations specified in the recipe, the film thickness of the solidified film deviates from the targe naturally. Then, a collapse rate of a pattern P may possibly increase. Therefore, it is necessary to perform operation such as concentration adjustment so that the concentration becomes a given value, which causes problems such as reduction of throughput. On the other hand, according to the present embodiment, the substrate is rotated at the number of rotations adjusted for obtaining the target solidified film thickness in accordance with the relationship among the concentration, the target solidified film thickness, and the number of rotations in the entire surface coating step. Consequently, even when treatment is determined inappropriate due to deviation of the concentration from the given value, factors causing inappropriate treatment can be absorbed by rotating the substrate at the number of rotations based on the relationship described above. As a result, the substrate can be treated without reducing throughput or increasing manufacturing costs.

Moreover, in the present embodiment, a variation in the concentration can be detected in the step S2 before supplying the solidified film forming liquid to the substrate. As a result, the number of rotations for solidified film formation can be changed without hurrying.

### Second Embodiment

The following describes a second embodiment of the present invention with reference to the drawings.

### 4-1. Outline of Substrate Treating Apparatus

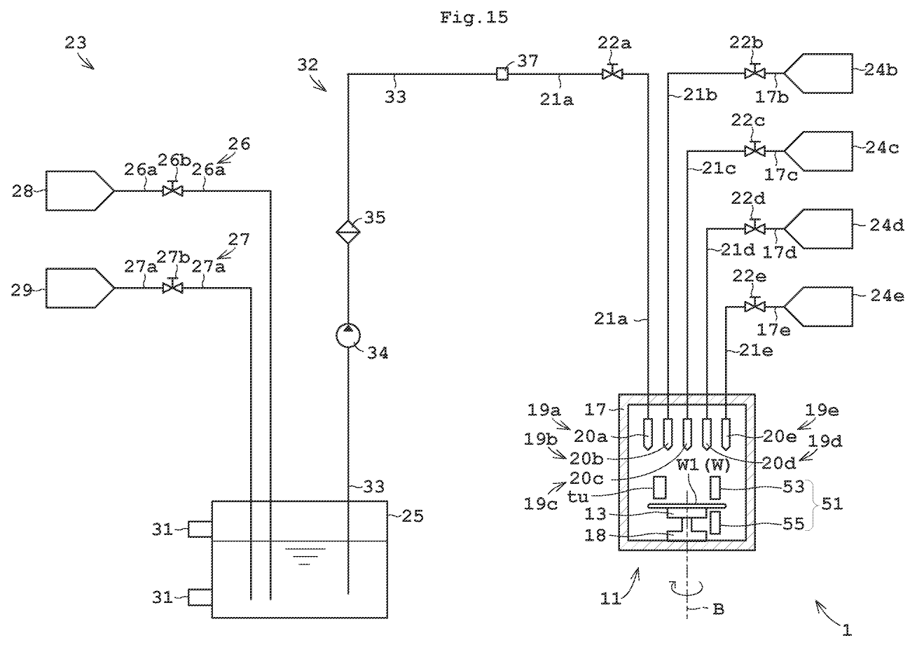

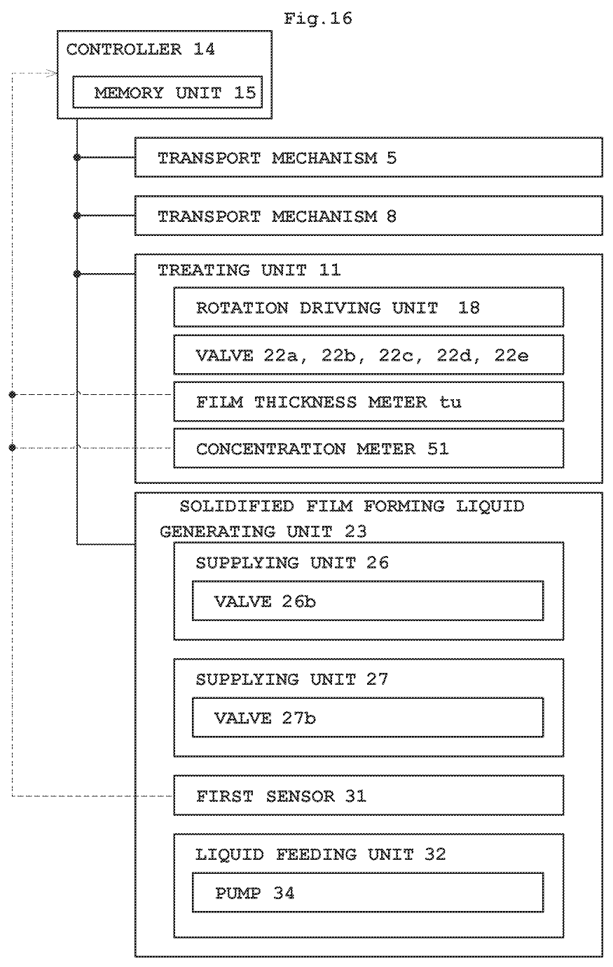

FIG. 15 illustrates configurations of a treating unit and a solidified film forming liquid generating unit of a substrate treating apparatus according to a second embodiment. FIG. 16 is a block diagram of the substrate treating apparatus according to the second embodiment.

Since the overall configuration of a substrate treating apparatus 1 is the same as that of the first embodiment described above, illustration and description thereof will be omitted.

In a solidified film forming liquid generating unit 23 in the second embodiment, a liquid feeding unit 32 does not include a concentration meter 36.

A treating unit 11 in the second embodiment includes a concentration meter 51. Specifically, a casing 17 includes therein the concentration meter 51. The concentration meter 51 is of a non-contact type. The concentration meter 51 detects a concentration of a sublimable substance in a solidified film forming liquid. The concentration meter 51 includes a transmitter 53 and a receiver 55. The transmitter 53 and the receiver 55 are aligned across a substrate W in a vertical direction Z. The transmitter 53 and the receiver 55 overlap in plan view. The transmitter 53 and the receiver 55 are arranged outward of a substrate holder 13 and inward of an outer periphery edge of the substrate W in plan view. In other words, light from the concentration meter 51 is supplied to the substrate W only. In the present embodiment, the transmitter 53 is located above the substrate W and the receiver 55 is located below the substrate W. Here, a positional relationship between the transmitter 53 and the receiver 55 in the vertical direction Z may be inverted.

For example, the transmitter 53 applies light passing through the substrate W. The light is, for example, infrared light. The receiver 55 detects intensity of light. The concentration meter 51 calculates a concentration of the solidified film forming liquid supplied on the top face of the substrate W in accordance with the light applied from the transmitter 53 and the intensity of the light detected by the receiver 55. Since the intensity of the light attenuated by the substrate W itself held by the substrate holder 13 is known, the concentration of the solidified film forming liquid on the top face of the substrate W can be calculated based on the degree of attenuation of the light. That is, the attenuation on the top face of the substrate W becomes large as the concentration of the sublimable substance in the solidified film forming liquid becomes high, and thus light receiving intensity received by the receiver 55 becomes small. The solidified film forming liquid having a concentration known in advance is supplied to the substrate W, and light receiving intensity is detected by the receiver 55. Data from the concentration meter 51 that is obtained at a predetermined film thickness of the solidified film forming liquid by detecting light receiving intensity while changing the concentration is stored. This can detect a concentration of the solidified film forming liquid on the top face of the substrate W in accordance with the light receiving intensity in the receiver 55.

The concentration meter 51 described above corresponds to the “concentration detector” in the present invention. Instead of a transmission-type concentration meter 51, a reflection-type concentration meter may be adopted that calculates a concentration based on the light reflected on the top face of the substrate W.

The solidified film forming liquid generating unit 23 does not measure a concentration of the solidified film forming liquid, generated in a tank 25, with the liquid feeding unit 32. The solidified film forming liquid generating unit 23 measures a concentration of the solidified film forming liquid supplied to the top face of the substrate W from a nozzle 20a.

### 5-1. Operational Example

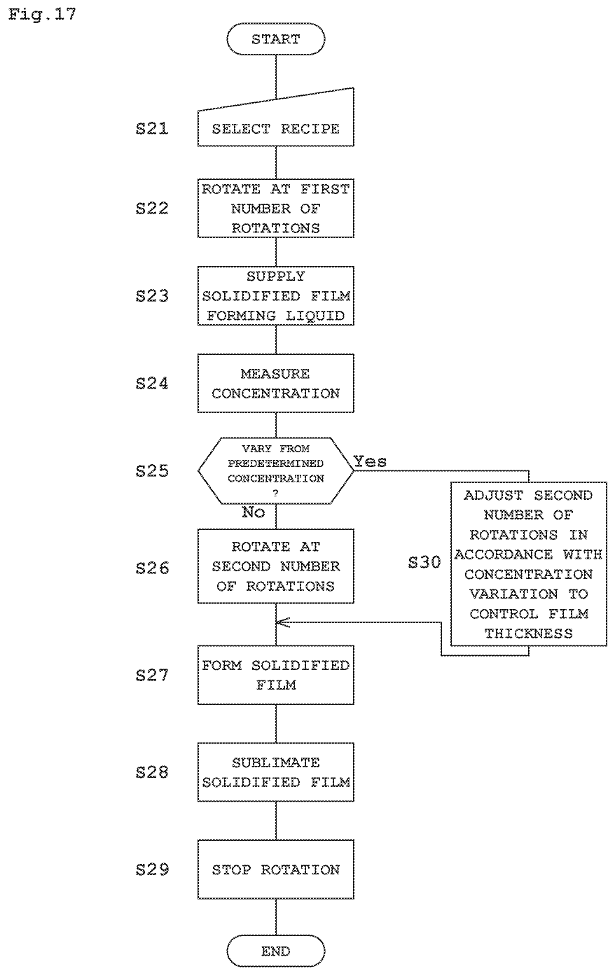

Reference is made to FIG. 17. FIG. 17 is a flowchart illustrating one example of substrate treatment.

The steps S21 to S23 are the same as the steps S1, S4, and S5 in the first embodiment described above, respectively.

### Step S24

The controller 14 controls the concentration meter 51 to measure a concentration of the sublimable substance in the solidified film forming liquid supplied to the top face of the substrate W.

### Step S25

The controller 14 divides treatment in accordance with the concentration received from the concentration meter 51. Specifically, the treatment is divided in accordance with the concentration of the sublimable substance in the solidified film forming liquid supplied to the top face of the substrate W from a supplying unit 19a. If the concentration does not vary from the predetermined concentration, the procedure is shifted to a step S26. If the concentration varies from the predetermined concentration, the procedure is shifted to a step S30.

### Steps S26 to S29

If the concentration does not vary from the predetermined concentration, the procedure is same as that in the steps S6 to S9 described in the first embodiment, and thus description thereof is to be omitted.

### Step S30

If the concentration measured on the top face of the substrate W varies from the predetermined concentration, the solidified film forming liquid having a predetermined concentration should be generated originally in the solidified film forming liquid generating unit 23. However, some failure may occur in valves 26b and 27b, or some failure may occur in a sublimable substance supplying source 28 or a solvent supplying source 29. In addition, even if the solidified film forming liquid having a predetermined concentration is generated in the tank 25, some failure may occur in a pipe 33 to vary the concentration during liquid supply. In the present embodiment, the solidified film having the target film thickness can be formed under such cases as above.

Specifically, similar treatment is performed to that in the step S10 in the first embodiment described above. That is, the controller 14 controls a number of rotations in accordance with the approximate equation. For example, in the equation (2), a film thickness y of a solidified film is fixed at the target film thickness, and a concentration is set as the concentration received from the concentration meter 51. The concentration determines a coefficient y₀, a coefficient a, and a coefficient b. The controller 14 calculates a number of rotations x from the equation (2) in such a manner as above. The controller 14 operates the rotation driving unit 18 to achieve the calculated number of rotations x.

The present embodiment produces the same effect as that of the first embodiment described above.

Moreover, the concentration is detected on the top face of the substrate W in the present embodiment. This can detect a variation in the concentration even if a supply system of the solidified film forming liquid, such as the liquid feeding unit 32 and the pipe 33, has some abnormality. Consequently, inappropriate treatment caused by the variation in the concentration can surely be prevented. In addition, the concentration meter 36 in the first embodiment may further be provided to perform concentration measurement by two steps. This makes it easy to identify a position where the cause of concentration variation occurs.

The present invention is not limited to the foregoing examples, but may be modified as follows.

(1) In each of the embodiments described above, the relationship among the concentration, the target solidified film thickness, and the number of rotations for solidified film formation has been described as one example of a relationship. However, the relationship is not limited to that of the solidified film in the present invention.

That is, as illustrated in FIG. 4, the film thickness at the time of measurement corresponds to a solidified film thickness in the method of measuring the film thickness when determining the relationship. However, the film thickness just before the time of measurement corresponds to a liquid film thickness. Accordingly, a film type at the time of measuring the film thickness is also a liquid film. Consequently, the relationship may be based on the concentration, the target liquid film thickness, and the number of rotations for liquid film formation. In this case, the target film thickness described above corresponds to the “target liquid film thickness” in the present invention, and the number of rotations for solidified film formation described above corresponds to the “number of rotations for liquid film formation” in the present invention.

(2) In each of the embodiments described above, the solidified film forming liquid is generated in the tank 25. However, the present invention is not limitative to this construction. For example, the sublimable substance and the solvent may be supplied to the pipe 33 while being mixed. Alternatively, the solidified film forming liquid controlled to have the predetermined concentration may be supplied to the pipe 33 directly.

(3) In each of the embodiments described above, the treatment with the equation (2) has been described as one example. Alternatively, the treatment may be performed with the equation (1).

(4) In each of the embodiments described above, the substrate treating apparatus 1 has been described including elements such as the transport mechanisms 5 and 8 as illustrated in FIG. 1 as one example. However, the present invention is not limitative to this construction. The present invention may be a substrate treating apparatus including the treating unit 11 and the controller 14 (memory unit 15) only, for example.

(5) In each of the embodiments described above, the sublimation promoting unit is formed with the supplying unit 19e and the nozzle 20e configured to dispense the first gas. However, the present invention is not limitative to this construction. For example, the sublimation promoting unit may be formed with a device that promotes sublimate through heating. Heating is preferably performed in a non-contact manner such as heating by a lamp heater or supplying high-temperature gases.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate treating method for drying a substrate on which a pattern is formed, the method comprising:
a solidified film forming liquid supplying step of supplying a solidified film forming liquid, containing a sublimable substance and a solvent, to the substrate;
an entire surface coating step of forming a liquid film of the solidified film forming liquid by rotating the substrate and spreading the solidified film forming liquid over an entire top face of the substrate;
a solidified film forming step of forming a solidified film containing the sublimable substance over the top face of the substrate by evaporating the solvent from the liquid film of the solidified film forming liquid and depositing the sublimable substance from the liquid film of the solidified film forming liquid; and
a sublimating step of sublimating the solidified film to remove the solidified film from the substrate, wherein
the entire surface coating step causes the substrate to rotate at a number of rotations for solidified film formation in accordance with a relationship among a concentration of the sublimable substance in the solidified film forming liquid, a target solidified film as a desired film thickness of the solidified film formed on the entire top face of the substrate by depositing the sublimable substance from the liquid film of the solidified film forming liquid, and the number of rotations for solidified film formation as a number of rotations of the substrate for forming the solidified film of the target solidified film when the concentration of the sublimable substance in the solidified film forming liquid is a predetermined concentration.

2. A substrate treating method for drying a substrate on which a pattern is formed, the method comprising:
a solidified film forming liquid supplying step of supplying a solidified film forming liquid, containing a sublimable substance and a solvent, to the substrate;
an entire surface coating step of forming a liquid film of the solidified film forming liquid by rotating the substrate and spreading the solidified film forming liquid over an entire top face of the substrate;
a solidified film forming step of forming a solidified film containing the sublimable substance over the top face of the substrate by evaporating the solvent from the liquid film of the solidified film forming liquid and depositing the sublimable substance from the liquid film of the solidified film forming liquid; and
a sublimating step of sublimating the solidified film to remove the solidified film from the substrate, wherein
the entire surface coating step causes the substrate to rotate at a number of rotations for liquid film formation in accordance with a relationship among a concentration of the sublimable substance in the solidified film forming liquid, a target liquid film thickness as a desired film thickness of the liquid film of the solidified film forming liquid, and the number of rotations for liquid film formation as a number of rotations of the substrate for forming the liquid film of the target liquid film thickness when the concentration of the sublimable substance in the solidified film forming liquid is a predetermined concentration.

3. The substrate treating method according to claim 1, wherein
the relationship is a correlation among the concentration, the target solidified film thickness, and the number of rotations for solidified film formation,
the correlation is expressed by an approximate equation representing a change in the target solidified film thickness with respect to a change in either the concentration or the number of rotations for solidified film formation, and
the number of rotations for solidified film formation is determined in accordance with the approximate equation.

4. The substrate treating method according to claim 2, wherein
the relationship is a correlation among the concentration, the target liquid film thickness, and the number of rotations for liquid film formation,
the correlation is expressed by an approximate equation representing a change in the target liquid film thickness with respect to a change in either the concentration or the number of rotations for liquid film formation, and
the number of rotations for liquid film formation is determined in accordance with the approximate equation.

5. The substrate treating method according to claim 1, wherein
when a variation of the concentration of the sublimable substance in the solidified film forming liquid occurs from the predetermined concentration, the number of rotations for solidified film formation is determined based on the relationship in accordance with the variation of the concentration.

6. The substrate treating method according to claim 2, wherein
when a variation of the concentration of the sublimable substance in the solidified film forming liquid occurs from the predetermined concentration, the number of rotations for liquid film formation is determined based on the relationship in accordance with the variation of the concentration.

7. The substrate treating method according to claim 1, wherein
before the substrate is rotated at the number of rotations for solidified film formation, the substrate is rotated at a number of rotations smaller than the number of rotations for solidified film formation for spreading the solidified film forming liquid over the entire top face of the substrate.

8. The substrate treating method according to claim 2, wherein
before the substrate is rotated at the number of rotations for liquid film formation, the substrate is rotated at a number of rotations smaller than the number of rotations for liquid film formation for spreading the solidified film forming liquid over the entire top face of the substrate.

9. The substrate treating method according to claim 1, wherein
the concentration of the solidified film forming liquid is measured before the solidified film forming liquid supplying step.

10. The substrate treating method according to claim 2, wherein
the concentration of the solidified film forming liquid is measured before the solidified film forming liquid supplying step.

11. The substrate treating method according to claim 1, wherein
the concentration of the solidified film forming liquid is measured at the top face of the substrate in the solidified film forming liquid supplying step.

12. The substrate treating method according to claim 2, wherein
the concentration of the solidified film forming liquid is measured at the top face of the substrate in the solidified film forming liquid supplying step.

13. A substrate treating apparatus for drying a substrate, the substrate treating apparatus comprising:
a spin holder configured to hold a substrate with a pattern formed thereon in a horizontal attitude and to rotate the substrate in a horizontal plane; and
a solidified film forming liquid supplying unit configured to supply a solidified film forming liquid, containing a sublimable substance and a solvent, to a top face of the substrate held by the spin holder,
the spin holder spinning to rotate the substrate, thereby spreading the solidified film forming liquid, supplied from the solidified film forming liquid supplying unit to the top face of the substrate, over the entire top face of the substrate to form a liquid film of the solidified film forming liquid, the solvent evaporating from the liquid film of the solidified film forming liquid and the sublimable substance is deposited from the liquid film of the solidified film forming liquid to form a solidified film, containing the sublimable substance, over the entire top face of the substrate, and the solidified film being sublimated and removed from the substrate, the substrate treating apparatus further comprising:
a memory unit configured to store in advance a relationship among a concentration of the sublimable substance in the solidified film forming liquid, a target solidified film thickness as a desired film thickness of the solidified film formed on the entire top face of the substrate by depositing the sublimable substance from the liquid film of the solidified film forming liquid, and a number of rotations for solidified film formation as a number of rotations of the substrate for forming the solidified film of the target solidified film thickness when the concentration of the sublimable substance in the solidified film forming liquid is a predetermined concentration; and
a controller configured to control the spin holder in accordance with the relationship stored in the memory unit such that the substrate rotates at the number of rotations for solidified film formation.

14. A substrate treating apparatus for drying a substrate, the substrate treating apparatus comprising:
a spin holder configured to hold a substrate with a pattern formed thereon in a horizontal attitude and to rotate the substrate in a horizontal plane; and
a solidified film forming liquid supplying unit configured to supply a solidified film forming liquid, containing a sublimable substance and a solvent, to a top face of the substrate held by the spin holder,
the spin holder spinning to rotate the substrate, thereby spreading the solidified film forming liquid, supplied from the solidified film forming liquid supplying unit to the top face of the substrate, over the entire top face of the substrate to form a liquid film of the solidified film forming liquid, the solvent evaporating from the liquid film of the solidified film forming liquid and the sublimable substance is deposited from the liquid film of the solidified film forming liquid to form a solidified film, containing the sublimable substance, over the entire top face of the substrate, and the solidified film being sublimated and removed from the substrate, the substrate treating apparatus further comprising:
a memory unit configured to store in advance a relationship among a concentration of the sublimable substance in the solidified film forming liquid, a target liquid film thickness as a desired film thickness of the solidified film forming liquid formed on the top face of the substrate, and a number of rotations for liquid film formation as a number of rotations of the substrate for forming the liquid film of the target liquid film thickness when the concentration of the sublimable substance in the solidified film forming liquid is a predetermined concentration; and
a controller configured to control the spin holder in accordance with the relationship stored in the memory unit such that the substrate rotates at the number of rotations for liquid film formation.

15. The substrate treating apparatus according to claim 13, wherein
the relationship stored in the memory unit is a correlation among the concentration, the target solidified film thickness, and the number of rotations for solidified film formation,
the correlation is a correlation expressed by an approximate equation representing a change in the target solidified film thickness with respect to a change in either the concentration or the number of rotations for solidified film formation, and
the controller reads the correlation among the concentration, the target solidified film thickness, and the number of rotations for solidified film formation from the memory unit, and determines the number of rotations for solidified film formation based on the correlation.

16. The substrate treating apparatus according to claim 14, wherein
the relationship stored in the memory unit is a correlation among the concentration, the target liquid film thickness, and the number of rotations for liquid film formation,
the correlation is a correlation expressed by an approximate equation representing a change in the target liquid film thickness with respect to a change in either the concentration or the number of rotations for liquid film formation, and
the controller reads the correlation among the concentration, the target liquid film thickness, and the number of rotations for liquid film formation from the memory unit, and determines the number of rotations for liquid film formation based on the correlation.

17. The substrate treating apparatus according to claim 13, wherein
before the controller controls the spin holder such that the substrate is rotated at the number of rotations for solidified film formation, the controller controls the spin holder so as to rotate the substrate at a number of rotations smaller than the number of rotations for solidified film formation for spreading the solidified film forming liquid over the entire top face of the substrate.

18. The substrate treating apparatus according to claim 14, wherein
before the controller controls the spin holder such that the substrate is rotated at the number of rotations for liquid film formation, the controller controls the spin holder so as to rotate the substrate at a number of rotations smaller than the number of rotations for liquid film formation for spreading the solidified film forming liquid over the entire top face of the substrate.

19. The substrate treating apparatus according to claim 13, wherein
the substrate treating apparatus further includes a concentration detector configured to detect a concentration of the sublimable substance in the solidified film forming liquid, and
when a detection result of the concentration detector reveals that a variation of the concentration of the sublimable substance in the solidified film forming liquid occurs from the predetermined concentration, the controller determines the number of rotations for solidified film formation based on the relationship stored in the memory unit in accordance with the variation of the concentration.

20. The substrate treating apparatus according to claim 14, wherein
the substrate treating apparatus further includes a concentration detector configured to detect a concentration of the sublimable substance in the solidified film forming liquid, and
when a detection result of the concentration detector reveals that a variation of the concentration of the sublimable substance in the solidified film forming liquid occurs from the predetermined concentration, the controller determines the number of rotations for liquid film formation based on the relationship stored in the memory unit in accordance with the variation of the concentration.

21. The substrate treating apparatus according to claim 19, wherein
the concentration detector detects a concentration of the sublimable substance in the solidified film forming liquid present at the solidified film forming liquid supplying unit.

22. The substrate treating apparatus according to claim 20, wherein
the concentration detector detects a concentration of the sublimable substance in the solidified film forming liquid present at the solidified film forming liquid supplying unit.

23. The substrate treating apparatus according to claim 19, wherein
the concentration detector detects a concentration of the sublimable substance in the solidified film forming liquid supplied to the top face of the substrate held by the spin holder.

24. The substrate treating apparatus according to claim 20, wherein
the concentration detector detects a concentration of the sublimable substance in the solidified film forming liquid supplied to the top face of the substrate held by the spin holder.

25. The substrate treating apparatus according to claim 21, wherein
the concentration detector detects a concentration of the sublimable substance in the solidified film forming liquid supplied to the top face of the substrate held by the spin holder.

26. The substrate treating apparatus according to claim 22, wherein
the concentration detector detects a concentration of the sublimable substance in the solidified film forming liquid supplied to the top face of the substrate held by the spin holder.

27. The substrate treating apparatus according to claim 13, further comprising:
an evaporation promoting unit configured to promote evaporation of the solvent from the liquid film of the solidified film forming liquid, wherein
the controller controls the evaporation promoting unit so as to promote the evaporation of the solvent from the liquid film.

28. The substrate treating apparatus according to claim 14, wherein
an evaporation promoting unit configured to promote evaporation of the solvent from the liquid film of the solidified film forming liquid, wherein
the controller controls the evaporation promoting unit so as to promote the evaporation of the solvent from the liquid film.

29. The substrate treating apparatus according to claim 13, further comprising:
a sublimation promoting unit configured to promote sublimation of the solidified film from the substrate, wherein
the controller controls the sublimation promoting unit so as to promote the sublimation of the solidified film from the substrate.

30. The substrate treating apparatus according to claim 14, wherein
a sublimation promoting unit configured to promote sublimation of the solidified film from the substrate, wherein
the controller controls the sublimation promoting unit so as to promote the sublimation of the solidified film from the substrate.
